(19) United States
(12) Patent Application Publication
(10) Pub. No.: US 2026/0223749 A1
(43) Pub. Date: Jul. 30, 2026

(54) COMPUTE-IN-MEMORY ARCHITECTURE UTILIZING 3D STACKED MEMORY WITH EMBEDDED LOGIC LAYER FOR HIGH-BANDWIDTH, LOW-POWER DATA PROCESSING

(71) Applicant: Hsilin Huang, Cupertino, CA (US)

(72) Inventor: Hsilin Huang, Cupertino, CA (US)

(21) Appl. No.: 19/572,802

(22) Filed: Mar. 19, 2026

Related U.S. Application Data
(63) Continuation-in-part of application No. 18/663,946, filed on May 14, 2024, now Pat. No. 12,585,467.
(60) Provisional application No. 63/614,761, filed on Dec. 26, 2023.

(51) Int. Cl. H10W 90/20; G06F 13/28; H10B 80/00; H10D 80/30; H10W 90/00

(52) U.S. Cl. CPC H10W 90/297; G06F 13/28; H10B 80/00; H10D 80/30; H10W 90/722; H10W 90/792; G06F 2213/28

(57) ABSTRACT

A processing unit including a base die, the base die having a logic layer; a plurality of stacked memory layers; wherein the logic layer is disposed beneath or between the plurality of stacked memory layers; wherein each of the plurality of stacked memory layers having a memory bank for performing localized computations; at least one or more through-silicon vias (TSVs), wherein the one or more through-silicon vias (TSV(s)) is/are configured to electrically interconnect each of the plurality of stacked memory layers to the at least one logic layer in a F2B or F2F configuration; wherein the logic layer is configured to perform arithmetic operations directly within or proximate to the plurality of vertically stacked memory layer; and wherein the logic layer having at least one buffer structure for maintaining at least one of a weight, a feature map, and a partial sum locally stagnant during computation.

### CROSS-REFERENCE TO RELATED APPLICATIONS

The present Utility patent application claims priority benefit of the U.S. nonprovisional patent application Ser. No. 18/663,946 filed May 14, 2024 and entitled “HIGH LEVEL GRAPH COMPUTING SYSTEM” under 35 U.S.C. 120 and further claims priority benefit of the U.S. provisional application for patent Ser. No. 63/614,761, entitled “High Level Graph Computing System”, filed on Dec. 26, 2023 under 35 U.S.C. 119(e). The contents of these related applications are incorporated herein by reference for all purposes to the extent that such subject matter is not inconsistent herewith or limiting hereof

### RELATED CO-PENDING U.S. PATENT APPLICATIONS

The following related U.S. patent application(s), submitted by at least one of the present Applicant(s)/Inventor(s) is/(are) recently co-pending: U.S. utility patent application Ser. No. 18/949,353, entitled “System, Method, and Program, Product for High Dimensional Computing”, submitted to the United States Patent and Trademark Office (USPTO) on Nov. 15, 2024.

### INCORPORATION BY REFERENCE OF SEQUENCE LISTING PROVIDED AS ATEXT FILE

Not applicable.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection by the author thereof The copyright owner has no objection to the facsimile reproduction by anyone of the patent document or patent disclosure for the purposes of referencing as patent prior art, as it appears in the Patent and Trademark Office, patent file or records, but otherwise reserves all copyright rights whatsoever.

### BACKGROUND OF THE RELEVANT PRIOR ART

One or more embodiments of the invention generally relate to semiconductor computing systems. More particularly, certain embodiments of the invention relate to a compute-in-memory (CIM) architecture integrated within 3D stacked memory devices for efficient data processing in artificial intelligence and edge computing environments.

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

Over the past several decades, the functionality and performance of computational systems have advanced at an extraordinary pace. At the heart of the progress lies the scaling of semiconductor devices. From dimensions measured in fractions of a millimeter in the 1960s to tens of nanometers in modern technologies. The continuous miniaturization has enabled the number of transistors per chip to grow exponentially, roughly doubling every 18 months, a trend famously known as Moore's Law. The impact of the trend has been profound, driving unprecedented growth in computational capability and transforming nearly every aspect of modern society.

The following is an example of a specific aspect in the prior art that, while expected to be helpful to further educate the reader as to additional aspects of the prior art, is not to be construed as limiting the present invention, or any embodiments thereof, to anything stated or implied therein or inferred thereupon. By way of educational background, another aspect of the prior art generally useful to be aware of is that there may be intense motivation to sustain the trajectory of performance improvement. Two major challenges threaten the continuation of traditional scaling. First, lithographic limitations may be approaching their physical boundaries. Second, even if smaller features could be fabricated, power density constraints would prevent reliable operation of such densely packed systems. As a result, achieving higher system performance has become increasingly difficult through scaling alone. Traditional PCB boards may connect various functional chips together. The recent CoWoS® technology utilizes 3D memory stacking and 2.5D integration to interconnect multiple dies within a single package. Three-dimensional (3D) integration technologies have emerged. The field of three-dimensional integrated circuits (3D ICs) has seen significant advancement through various interconnection technologies. Two notable approaches have been developed and commercialized by Taiwan Semiconductor Manufacturing Company (TSMC®).

TSMC's CoWoS® (Chip on Wafer on Substrate) represents a 2.5D/3D integration approach that utilizes a silicon interposer containing Through Silicon Vias (TSVs) to establish electrical connections between multiple dies. In this configuration, TSVs provide vertical electrical pathways through the silicon interposer, enabling communication between dies mounted on its surface. The interposer itself is then mounted onto a conventional substrate. The technology has been documented in the technical literature, including a 2013 IEEE publication titled “Test and debug strategy for TSMC CoWoS® stacking process based heterogeneous 3D IC: A silicon case study,” which describes the testing methodologies and debug strategies employed in the manufacturing process.

More recently, TSMC® introduced SoIC® (System on Integrated Chips), which represents a departure from TSV-based interconnection. SoIC® employs bumpless hybrid bonding technology to achieve three-dimensional heterogeneous integration. The front-end-of-line manufacturing process uses known-good-die (KGD) and creates direct copper-to-copper and dielectric-to-dielectric bonds, enabling ultra high-density interconnects without the need for traditional solder bumps or TSVs at the bonding interface. Technical details of the approach have been disclosed in TSMC's research publications, including “3D Multi-chip Integration with System on Integrated Chips (SoIC®),” available through TSMC® official research documentation on off-chip interconnect technologies.

FIG. 1A shows a comparison between (a) 2.5D CoWoS® (left) and (b) 3D SOIC™ (right).

Referring to FIG. 1A (a), 2.5D CoWoS® demonstrates an exemplary High Bandwidth Memory (HBM) package, in accordance with an embodiment of the present invention. In one embodiment of the present invention, one or more HBM stack(s) 10 are placed adjacent to a compute 12 and logic die 14. A silicon interposer 16 may serve as the foundational substrate, providing high-density interconnections between the HBM and the compute/logic die.

The HBM module comprises, without limitation, multiple HBM DRAM dies 10 stacked in a 3D layer-to-layer configuration atop a Base DRAM die 18. The Base DRAM die may facilitate the signaling and serves as the primary interface for the stack.

Both HBM stack (Base DRAM die included) 10 and high-performance compute 12 and logic die 14 are mounted onto Silicon Interposer 16. Connections between the dies and within the interposer are made using micro-bumps (uBumps) 22 and internal wiring. The interposer provides high-density, high-speed routing between the disparate dies.

Interposer 16 may connect to a Package Substrate 20. The connection is typically achieved via a C4 (Controlled Collapse Chip Connection) copper (Cu) uBumps 24. The traces then route to external Package Balls (or solder balls) 26, which may serve as the final connection points for mounting the entire assembly onto the Circuit Board (Printed Circuit Board—PCB) 28. A few traces may exit the interposer/package to form the external pins of the package.

Referring to FIG. 1A (b), 3D SOIC™ demonstrates an exemplary High Bandwidth Memory (HBM) package structure 10 on top of logic die 14, in accordance with an embodiment of the present invention. In one embodiment of the present invention, three-dimensional (3D) integration technologies may offer the promise of increasing system performance even in the absence of scaling. The main advantages of 3D integration may be summed up as follows: (1) 3D decreases the interconnect distance between regions of a chip, decreasing wiring parasitic and interconnect delay times, (2) 3D may dramatically increase the number of interconnects and therefore increase the aggregate communication bandwidth between chips, and (3) 3D may allow dissimilar functions, technologies, and materials to be integrated.

Both technologies may address the challenge of integrating multiple dies in a three-dimensional configuration, through fundamentally different interconnection methodologies including TSV-based for CoWoS® and hybrid bonding for SoIC™

Given the historical gains, there is intense motivation to sustain the trajectory of performance improvement. However, two major challenges may threaten the continuation of traditional scaling. First, lithographic limitations may be approaching their physical boundaries. Second, even if smaller features could be fabricated, power density constraints may prevent reliable operation of such densely packed systems. As a result, achieving higher system performance has become increasingly difficult through scaling alone.

From a computing architecture perspective, conventional computer designs separate computation from memory, resulting in extensive data movement between the central processing unit (CPU), memory, and storage. The frequent data transfer introduces latency and power consumption, especially in data-intensive tasks such as neural network inference and multimedia processing.

Existing CIM designs typically operate on 2D memory arrays with limited bandwidth and scaling potential. Moreover, communication between multiple memory banks remains constrained by planar interconnects, reducing performance for large-scale matrix operations.

Current HMC™ and HBM-based designs rely primarily on external processors or controllers for computation, failing to achieve the full potential of compute-in-memory processing, where the arithmetic is performed locally within the stacked memory structure itself. While the structure increases bandwidth compared to traditional planar DRAM, computation remains external to the memory, and significant interposer routing distance still introduces latency and power overhead.

There is a need for a 3D stacked compute-in-memory architecture that integrates computation directly within or adjacent to stacked memory layers, minimizing data movement while enabling parallel high-speed computation.

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1A shows a comparison between (a) 2.5D CoWoS® (left) and (b) 3D SOIC™ (right).

FIG. 1B is an illustration of an exemplary Bumps/Mirco-Bumps and Direct Bonding/Hyper-Bonding, in accordance with an embodiment of the present invention;

FIG. 1C illustrates various exemplary 3D stacking configurations for a memory die and a compute die, in accordance with an embodiment of the present invention;

FIG. 1D illustrates an exemplary CoWoS® packaging configuration in which the memory dies are arranged in a face-to-back stacking configuration, in accordance with an embodiment of the present invention;

FIG. 2A illustrates an exemplary back-to-back (B2B) stacked configuration of compute and memory dies, in accordance with an embodiment of the present invention;

FIG. 2B illustrates an exemplary face-to-back (F2B) stacked configuration of compute and memory dies, in accordance with an embodiment of the present invention;

FIG. 2C illustrates an exemplary configuration similar to that shown in FIG. 2B, in accordance with an embodiment of the present invention;

FIG. 2D illustrates an exemplary face-to-face (F2F) stacked configuration of compute and memory dies, in accordance with an embodiment of the present invention;

FIG. 2E illustrates an exemplary face-to-back (F2B) stacked configuration of compute and memory dies, in accordance with an embodiment of the present invention;

FIG. 3A illustrates an exemplary Multi-Dimensional Tensor Descriptor and Hierarchical Execution Model, in accordance with an embodiment of the present invention;

FIG. 3B illustrates an exemplary Directional Broadcast and Reduction Across Three-Dimensional Compute Space, in accordance with an embodiment of the present invention;

FIG. 3C illustrates an exemplary Stationary Buffer Architecture with Directional Broadcast and Partial-Sum Accumulation, in accordance with an embodiment of the present invention;

FIG. 4 illustrates an exemplary Overall 3D Stack Architecture in a compute-in-memory device, in accordance with an embodiment of the present invention;

FIG. 5 illustrates an exemplary 4-core NPU architecture in which all cores are interconnected through a Network-on-Chip (NoC), in accordance with an embodiment of the present invention;

FIG. 6A illustrates an exemplary DMA Controller with Copy Module, in accordance with an embodiment of the present invention;

FIG. 6B illustrates an exemplary Logic Layer Architecture with upper DRAM and external DRAM and Compute in Memory, in accordance with an embodiment of the present invention;

FIG. 7 illustrates an exemplary Multiple Core SOC, in accordance with an embodiment of the present invention;

FIG. 8A illustrates an exemplary core-to-core interconnection using a Network-on-Chip (NoC), in accordance with an embodiment of the present invention;

FIG. 8B illustrates an exemplary NoC topology for core-to-core and chip-to-chip communication, in accordance with an embodiment of the present invention;

FIG. 8C illustrates an exemplary NOC Queue and Credit for core-to-core communication, in accordance with an embodiment of the present invention;

FIG. 9 illustrates an exemplary die-to-die with memory interfaces, in accordance with an embodiment of the present invention; and,

FIG. 10 is a block diagram depicting an exemplary client/server system which may be used by an exemplary web-enabled/networked embodiment of the present invention.

Unless otherwise indicated illustrations in the figures are not necessarily drawn to scale.

### DETAILED DESCRIPTION OF SOME EMBODIMENTS

The present invention is best understood by reference to the detailed figures and description set forth herein.

### 3D Memory Stacking:

The architecture may employ a 3D-stacked memory system, where memory may be vertically bonded on top of an NPU logic die using advanced stacking techniques, including but not limited to:
Face-to-Face (F2F) bonding
Face-to-Back (F2B) bonding
Hybrid bonding with TSVs or micro-bump interconnects

The primary purpose of the stacking may be to:
Minimize the wire length between the compute core and the memory
Reduce a capacitance and power required for frequent high-bandwidth data transfers
Increase bandwidth density without expanding the 2D footprint of the chip
Improve signal integrity by reducing driver load

By stacking memory vertically above the logic die, the design may allow for dense, energy-efficient data movement between the NPU and the 3D memory. The memory interface may be localized through high-density vertical interconnects rather than long lateral wires.

To avoid signal interference from high-speed interfaces such as, without limitation, LPDDR and PCIe®, all such IO signals may be routed through the substrate beneath the NPU logic die, and may be physically separated from the memory stack, ensuring clean power and signal domains for the memory subsystem.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

All words of approximation as used in the present disclosure and claims should be construed to mean “approximate,” rather than “perfect,” and may accordingly be employed as a meaningful modifier to any other word, specified parameter, quantity, quality, or concept. Words of approximation, include, yet are not limited to terms such as “substantial”, “nearly”, “almost”, “about”, “generally”, “largely”, “essentially”, “closely approximate”, etc.

As will be established in some detail below, it is well settled law, as early as 1939, that words of approximation are not indefinite in the claims even when such limits are not defined or specified in the specification.

For example, see Ex parte Mallory, 52 USPQ 297, 297 (Pat. Off Bd. App. 1941) where the court said “The examiner has held that most of the claims are inaccurate because apparently the laminar film will not be entirely eliminated. The claims specify that the film is “substantially” eliminated and for the intended purpose, it is believed that the slight portion of the film which may remain is negligible. We are of the view, therefore, that the claims may be regarded as sufficiently accurate.”

Note that claims need only “reasonably apprise those skilled in the art” as to their scope to satisfy the definiteness requirement. See Energy Absorption Sys., Inc. v. Roadway Safety Servs., Inc., Civ. App. 96-1264, slip op. at 10 (Fed. Cir. Jul. 3, 1997) (unpublished) Hybridtech v. Monoclonal Antibodies, Inc., 802 F.2d 1367, 1385, 231 USPQ 81, 94 (Fed. Cir. 1986), cert. denied, 480 U.S. 947 (1987). In addition, the use of modifiers in the claim, like “generally” and “substantial,” does not by itself render the claims indefinite. See Seattle Box Co. v. Industrial Crating & Packing, Inc., 731 F.2d 818, 828-29, 221 USPQ 568, 575-76 (Fed. Cir. 1984).

Moreover, the ordinary and customary meaning of terms like “substantially” includes “reasonably close to, nearly, almost, about”, connoting a term of approximation. See In re Frye, Appeal No. 2009-006013, 94 USPQ2d 1072, 1077, 2010 WL 889747 (B.P.A.I. 2010) Depending on its usage, the word “substantially” can denote either language of approximation or language of magnitude. Deering Precision Instruments, L.L.C. v. Vector Distribution Sys., Inc., 347 F.3d 1314, 1323 (Fed. Cir. 2003) (recognizing the “dual ordinary meaning of th[e] term [“substantially” ] as connoting a term of approximation or a term of magnitude”). Here, when referring to the “substantially halfway” limitation, the Specification uses the word “approximately” as a substitute for the word “substantially” (Fact 4). (Fact 4). The ordinary meaning of “substantially halfway” is thus reasonably close to or nearly at the midpoint between the forwardmost point of the upper or outsole and the rearward most point of the upper or outsole.

Similarly, the term ‘substantially’ is well recognized in case law to have the dual ordinary meaning of connoting a term of approximation or a term of magnitude. See Dana Corp. v. American Axle & Manufacturing, Inc., Civ. App. 04-1116, 2004 U.S. App. LEXIS 18265, *13-14 (Fed. Cir. Aug. 27, 2004) (unpublished). The term “substantially” is commonly used by claim drafters to indicate approximation. See Cordis Corp. v. Medtronic AVE Inc., 339 F.3d 1352, 1360 (Fed. Cir. 2003) (“The patents do not set out any numerical standard by which to determine whether the thickness of the wall surface is ‘substantially uniform.’ The term ‘substantially,’ as used in this context, denotes approximation. Thus, the walls must be of largely or approximately uniform thickness.”); see also Deering Precision Instruments, LLC v. Vector Distribution Sys., Inc., 347 F.3d 1314, 1322 (Fed. Cir. 2003); Epcon Gas Sys., Inc. v. Bauer Compressors, Inc., 279 F.3d 1022, 1031 (Fed. Cir. 2002). We find that the term “substantially” was used in just such a manner in the claims of the patents-in-suit: “substantially uniform wall thickness” denotes a wall thickness with approximate uniformity.

It should also be noted that such words of approximation as contemplated in the foregoing clearly limits the scope of claims such as saying ‘generally parallel’ such that the adverb ‘generally’ does not broaden the meaning of parallel. Accordingly, it is well settled that such words of approximation as contemplated in the foregoing (e.g., like the phrase ‘generally parallel’) envisions some amount of deviation from perfection (e.g., not exactly parallel), and that such words of approximation as contemplated in the foregoing are descriptive terms commonly used in patent claims to avoid a strict numerical boundary to the specified parameter. To the extent that the plain language of the claims relying on such words of approximation as contemplated in the foregoing are clear and uncontradicted by anything in the written description herein or the figures thereof, it is improper to rely upon the present written description, the figures, or the prosecution history to add limitations to any of the claim of the present invention with respect to such words of approximation as contemplated in the foregoing. That is, under such circumstances, relying on the written description and prosecution history to reject the ordinary and customary meanings of the words themselves is impermissible. See, for example, Liquid Dynamics Corp. v. Vaughan Co., 355 F.3d 1361, 69 USPQ2d 1595, 1600-01 (Fed. Cir. 2004). The plain language of phrase 2 requires a “substantial helical flow.” The term “substantial” is a meaningful modifier implying “approximate,” rather than “perfect.” In Cordis Corp. v. Medtronic AVE, Inc., 339 F.3d 1352, 1361 (Fed. Cir. 2003), the district court imposed a precise numeric constraint on the term “substantially uniform thickness.” We noted that the proper interpretation of this term was “of largely or approximately uniform thickness” unless something in the prosecution history imposed the “clear and unmistakable disclaimer” needed for narrowing beyond this simple-language interpretation. Id. In Anchor Wall Systems v. Rockwood Retaining Walls, Inc., 340 F.3d 1298, 1311 (Fed. Cir. 2003)” Id. at 1311. Similarly, the plain language of Claim 1 requires neither a perfectly helical flow nor a flow that returns precisely to the center after one rotation (a limitation that arises only as a logical consequence of requiring a perfectly helical flow).

The reader should appreciate that case law generally recognizes a dual ordinary meaning of such words of approximation, as contemplated in the foregoing, as connoting a term of approximation or a term of magnitude; e.g., see Deering Precision Instruments, L.L.C. v. Vector Distrib. Sys., Inc., 347 F.3d 1314, 68 USPQ2d 1716, 1721 (Fed. Cir. 2003), cert. denied, 124 S. Ct. 1426 (2004) where the court was asked to construe the meaning of the term “substantially” in a patent claim. Also see Epcon, 279 F.3d at 1031 (“The phrase ‘substantially constant’ denotes language of approximation, while the phrase ‘substantially below’ signifies language of magnitude, i.e., not insubstantial.”). Also, see, e.g., Epcon Gas Sys., Inc. v. Bauer Compressors, Inc., 279 F.3d 1022 (Fed. Cir. 2002) (construing the terms “substantially constant” and “substantially below”); Zodiac Pool Care, Inc. v. Hoffinger Indus., Inc., 206 F.3d 1408 (Fed. Cir. 2000) (construing the term “substantially inward”); York Prods., Inc. v. Cent. Tractor Farm & Family Ctr., 99 F.3d 1568 (Fed. Cir. 1996) (construing the term “substantially the entire height thereof”); Tex. Instruments Inc. v. Cypress Semiconductor Corp., 90 F.3d 1558 (Fed. Cir. 1996) (construing the term “substantially in the common plane”). In conducting their analysis, the court instructed to begin with the ordinary meaning of the claim terms to one of ordinary skill in the art. Prima Tek, 318 F.3d at 1148. Reference to dictionaries and our cases indicates that the term “substantially” has numerous ordinary meanings. As the district court stated, “substantially” can mean “significantly” or “considerably.” The term “substantially” can also mean “largely” or “essentially.” Webster's New 20th Century Dictionary 1817 (1983).

Words of approximation, as contemplated in the foregoing, may also be used in phrases establishing approximate ranges or limits, where the end points are inclusive and approximate, not perfect; e.g., see AK Steel Corp. v. Sollac, 344 F.3d 1234, 68 USPQ2d 1280, 1285 (Fed. Cir. 2003) where it where the court said [W]e conclude that the ordinary meaning of the phrase “up to about 10%” includes the “about 10%” endpoint. As pointed out by AK Steel, when an object of the preposition “up to” is nonnumeric, the most natural meaning is to exclude the object (e.g., painting the wall up to the door). On the other hand, as pointed out by Sollac, when the object is a numerical limit, the normal meaning is to include that upper numerical limit (e.g., counting up to ten, seating capacity for up to seven passengers). Because we have here a numerical limit “about 10%” the ordinary meaning is that that endpoint is included.

In the present specification and claims, a goal of employment of such words of approximation, as contemplated in the foregoing, is to avoid a strict numerical boundary to the modified specified parameter, as sanctioned by Pall Corp. v. Micron Separations, Inc., 66 F.3d 1211, 1217, 36 USPQ2d 1225, 1229 (Fed. Cir. 1995) where it states “It is well established that when the term “substantially” serves reasonably to describe the subject matter so that its scope would be understood by persons in the field of the invention, and to distinguish the claimed subject matter from the prior art, it is not indefinite.” Likewise see Verve LLC v. Crane Cams Inc., 311 F.3d 1116, 65 USPQ2d 1051, 1054 (Fed. Cir. 2002). Expressions such as “substantially” are used in patent documents when warranted by the nature of the invention, in order to accommodate the minor variations that may be appropriate to secure the invention. Such usage may well satisfy the charge to “particularly point out and distinctly claim” the invention, 35 U.S.C. § 112, and indeed may be necessary in order to provide the inventor with the benefit of his invention. In Andrew Corp. v. Gabriel Elecs. Inc., 847 F.2d 819, 821-22, 6 USPQ2d 2010, 2013 (Fed. Cir. 1988) the court explained that usages such as “substantially equal” and “closely approximate” may serve to describe the invention with precision appropriate to the technology and without intruding on the prior art. The court again explained in Ecolab Inc. v. Envirochem, Inc., 264 F.3d 1358, 1367, 60 USPQ2d 1173, 1179 (Fed. Cir. 2001) that “like the term ‘about,’ the term ‘substantially’ is a descriptive term commonly used in patent claims to ‘avoid a strict numerical boundary to the specified parameter, see Ecolab Inc. v. Envirochem Inc., 264 F.3d 1358, 60 USPQ2d 1173, 1179 (Fed. Cir. 2001) where the court found that the use of the term “substantially” to modify the term “uniform” does not render this phrase so unclear such that there is no means by which to ascertain the claim scope.

Similarly, other courts have noted that like the term “about,” the term “substantially” is a descriptive term commonly used in patent claims to “avoid a strict numerical boundary to the specified parameter.”; e.g., see Pall Corp. v. Micron Seps., 66 F.3d 1211, 1217, 36 USPQ2d 1225, 1229 (Fed. Cir. 1995); see, e.g., Andrew Corp. v. Gabriel Elecs. Inc., 847 F.2d 819, 821-22, 6 USPQ2d 2010, 2013 (Fed. Cir. 1988) (noting that terms such as “approach each other,” “close to,” “substantially equal,” and “closely approximate” are ubiquitously used in patent claims and that such usages, when serving reasonably to describe the claimed subject matter to those of skill in the field of the invention, and to distinguish the claimed subject matter from the prior art, have been accepted in patent examination and upheld by the courts). In this case, “substantially” avoids the strict 100% nonuniformity boundary.

Indeed, the foregoing sanctioning of such words of approximation, as contemplated in the foregoing, has been established as early as 1939, see Ex parte Mallory, 52 USPQ 297, 297 (Pat. Off Bd. App. 1941) where, for example, the court said “the claims specify that the film is “substantially” eliminated and for the intended purpose, it is believed that the slight portion of the film which may remain is negligible. We are of the view, therefore, that the claims may be regarded as sufficiently accurate.” Similarly, In re Hutchison, 104 F.2d 829, 42 USPQ 90, 93 (C.C.P.A. 1939) the court said “It is realized that “substantial distance” is a relative and somewhat indefinite term, or phrase, but terms and phrases of this character are not uncommon in patents in cases where, according to the art involved, the meaning can be determined with reasonable clearness.”

Hence, for at least the forgoing reason, Applicants submit that it is improper for any examiner to hold as indefinite any claims of the present patent that employ any words of approximation.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will be described in detail below with reference to embodiments thereof as illustrated in the accompanying drawings.

References to a “device,” an “apparatus,” a “system,” etc., in the preamble of a claim should be construed broadly to mean “any structure meeting the claim terms” exempt for any specific structure(s)/type(s) that has/(have) been explicitly disavowed or excluded or admitted/implied as prior art in the present specification or incapable of enabling an object/aspect/goal of the invention. Furthermore, where the present specification discloses an object, aspect, function, goal, result, or advantage of the invention that a specific prior art structure and/or method step is similarly capable of performing yet in a very different way, the present invention disclosure is intended to and shall also implicitly include and cover additional corresponding alternative embodiments that are otherwise identical to that explicitly disclosed except that they exclude such prior art structure(s)/step(s), and shall accordingly be deemed as providing sufficient disclosure to support a corresponding negative limitation in a claim claiming such alternative embodiment(s), which exclude such very different prior art structure(s)/step(s) way(s).

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

References to “one embodiment,” “an embodiment,” “example embodiment,” “various embodiments,” “some embodiments,” “embodiments of the invention,” etc., may indicate that the embodiment(s) of the invention so described may include a particular feature, structure, or characteristic, but not every possible embodiment of the invention necessarily includes the particular feature, structure, or characteristic. Further, repeated use of the phrase “in one embodiment,” or “in an exemplary embodiment,” “an embodiment,” do not necessarily refer to the same embodiment, although they may. Moreover, any use of phrases like “embodiments” in connection with “the invention” are never meant to characterize that all embodiments of the invention must include the particular feature, structure, or characteristic, and should instead be understood to mean “at least some embodiments of the invention” include the stated particular feature, structure, or characteristic.

References to “user”, or any similar term, as used herein, may mean a human or non-human user thereof. Moreover, “user”, or any similar term, as used herein, unless expressly stipulated otherwise, is contemplated to mean users at any stage of the usage process, to include, without limitation, direct user(s), intermediate user(s), indirect user(s), and end user(s). The meaning of “user”, or any similar term, as used herein, should not be otherwise inferred or induced by any pattern(s) of description, embodiments, examples, or referenced prior art that may (or may not) be provided in the present patent.

References to “end user”, or any similar term, as used herein, is generally intended to mean late-stage user(s) as opposed to early-stage user(s). Hence, it is contemplated that there may be a multiplicity of different types of “end user” near the end stage of the usage process. Where applicable, especially with respect to distribution channels of embodiments of the invention comprising consumed retail products/services thereof (as opposed to sellers/vendors or Original Equipment Manufacturers), examples of an “end user” may include, without limitation, a “consumer”, “buyer”, “customer”, “purchaser”, “shopper”, “enjoyer”, “viewer”, or individual person or non-human thing benefiting in any way, directly or indirectly, from use of or interaction with some aspect of the present invention.

In some situations, some embodiments of the present invention may provide beneficial usage to more than one stage or type of usage in the foregoing usage process. In such cases where multiple embodiments targeting various stages of the usage process are described, references to “end user”, or any similar term, as used therein, are generally intended to not include the user that is the furthest removed, in the foregoing usage process, from the final user therein of an embodiment of the present invention.

Where applicable, especially with respect to retail distribution channels of embodiments of the invention, intermediate user(s) may include, without limitation, any individual person or non-human thing benefiting in any way, directly or indirectly, from use of, or interaction with, some aspect of the present invention with respect to selling, vending, Original Equipment Manufacturing, marketing, merchandising, distributing, service providing, and the like thereof.

References to “person”, “individual”, “human”, “a party”, “animal”, “creature”, or any similar term, as used herein, even if the context or particular embodiment implies living user, maker, or participant, it should be understood that such characterizations are sole by way of example, and not limitation, in that it is contemplated that any such usage, making, or participation by a living entity in connection with making, using, and/or participating, in any way, with embodiments of the present invention may be substituted by such similar performed by a suitably configured non-living entity, to include, without limitation, automated machines, robots, humanoids, computational systems, information processing systems, artificially intelligent systems, and the like. It is further contemplated that those skilled in the art will readily recognize the practical situations where such living makers, users, and/or participants with embodiments of the present invention may be in whole, or in part, replaced with such non-living makers, users, and/or participants with embodiments of the present invention. Likewise, when those skilled in the art identify such practical situations where such living makers, users, and/or participants with embodiments of the present invention may be in whole, or in part, replaced with such non-living makers, it will be readily apparent in light of the teachings of the present invention how to adapt the described embodiments to be suitable for such non-living makers, users, and/or participants with embodiments of the present invention. Thus, the invention is thus to also cover all such modifications, equivalents, and alternatives falling within the spirit and scope of such adaptations and modifications, at least in part, for such non-living entities.

Headings provided herein are for convenience and are not to be taken as limiting the disclosure in any way.

The enumerated listing of items does not imply that any or all of the items are mutually exclusive, unless expressly specified otherwise.

It is understood that the use of specific component, device and/or parameter names are for example only and not meant to imply any limitations on the invention. The invention may thus be implemented with different nomenclature/terminology utilized to describe the mechanisms/units/structures/components/devices/parameters herein, without limitation. Each term utilized herein is to be given its broadest interpretation given the context in which that term is utilized.

Terminology. The following paragraphs provide definitions and/or context for terms found in this disclosure (including the appended claims):

“Comprising” And “contain” and variations of them—Such terms are open-ended and mean “including but not limited to”. When employed in the appended claims, this term does not foreclose additional structure or steps. Consider a claim that recites: “A memory controller comprising a system cache . . . .” Such a claim does not foreclose the memory controller from including additional components (e.g., a memory channel unit, a switch).

“Configured To.” Various units, circuits, or other components may be described or claimed as “configured to” perform a task or tasks. In such contexts, “configured to” or “operable for” is used to connote structure by indicating that the mechanisms/units/circuits/components include structure (e.g., circuitry and/or mechanisms) that performs the task or tasks during operation. As such, the mechanisms/unit/circuit/component can be said to be configured to (or be operable) for perform(ing) the task even when the specified mechanisms/unit/circuit/component is not currently operational (e.g., is not on). The mechanisms/units/circuits/components used with the “configured to” or “operable for” language include hardware—for example, mechanisms, structures, electronics, circuits, memory storing program instructions executable to implement the operation, etc. Reciting that a mechanism/unit/circuit/component is “configured to” or “operable for” perform(ing) one or more tasks is expressly intended not to invoke 35 U.S.C. sctn.112, sixth paragraph, for that mechanism/unit/circuit/component. “Configured to” may also include adapting a manufacturing process to fabricate devices or components that are adapted to implement or perform one or more tasks.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

The terms “a”, “an” and “the” mean “one or more”, unless expressly specified otherwise.

All terms of exemplary language (e.g., including, without limitation, “such as”, “like”, “for example”, “for instance”, “similar to”, etc.) are not exclusive of any other, potentially, unrelated, types of examples; thus, implicitly mean “by way of example, and not limitation . . . ”, unless expressly specified otherwise.

Unless otherwise indicated, all numbers expressing conditions, concentrations, dimensions, and so forth used in the specification and claims are to be understood as being modified in all instances by the term “about.” Accordingly, unless indicated to the contrary, the numerical parameters set forth in the following specification and attached claims are approximations that may vary depending at least upon a specific analytical technique.

The term “comprising,” which is synonymous with “including,” “containing,” or “characterized by” is inclusive or open-ended and does not exclude additional, unrecited elements or method steps. “Comprising” is a term of art used in claim language which means that the named claim elements are essential, but other claim elements may be added and still form a construct within the scope of the claim.

As used herein, the phase “consisting of” excludes any element, step, or ingredient not specified in the claim. When the phrase “consists of” (or variations thereof) appears in a clause of the body of a claim, rather than immediately following the preamble, it limits only the element set forth in that clause; other elements are not excluded from the claim as a whole. As used herein, the phase “consisting essentially of” and “consisting of” limits the scope of a claim to the specified elements or method steps, plus those that do not materially affect the basis and novel characteristic(s) of the claimed subject matter (see Norian Corp. v Stryker Corp., 363 F.3d 1321, 1331-32, 70 USPQ2d 1508, Fed. Cir. 2004). Moreover, for any claim of the present invention which claims an embodiment “consisting essentially of” or “consisting of” a certain set of elements of any herein described embodiment it shall be understood as obvious by those skilled in the art that the present invention also covers all possible varying scope variants of any described embodiment(s) that are each exclusively (i.e., “consisting essentially of”) functional subsets or functional combination thereof such that each of these plurality of exclusive varying scope variants each consists essentially of any functional subset(s) and/or functional combination(s) of any set of elements of any described embodiment(s) to the exclusion of any others not set forth therein. That is, it is contemplated that it will be obvious to those skilled how to create a multiplicity of alternate embodiments of the present invention that simply consisting essentially of a certain functional combination of elements of any described embodiment(s) to the exclusion of any others not set forth therein, and the invention thus covers all such exclusive embodiments as if they were each described herein.

With respect to the terms “comprising,” “consisting of,” and “consisting essentially of,” where one of these three terms is used herein, the disclosed and claimed subject matter may include the use of either of the other two terms. Thus, in some embodiments not otherwise explicitly recited, any instance of “comprising” may be replaced by “consisting of” or, alternatively, by “consisting essentially of”, and thus, for the purposes of claim support and construction for “consisting of” format claims, such replacements operate to create yet other alternative embodiments “consisting essentially of” only the elements recited in the original “comprising” embodiment to the exclusion of all other elements.

Moreover, any claim limitation phrased in functional limitation terms covered by 35 USC § 112(6) (post AIA 112(f)) which has a preamble invoking the closed terms “consisting of,” or “consisting essentially of,” should be understood to mean that the corresponding structure(s) disclosed herein define the exact metes and bounds of what the so claimed invention embodiment(s) consists of, or consisting essentially of, to the exclusion of any other elements which do not materially affect the intended purpose of the so claimed embodiment(s).

Devices or system modules that are in at least general communication with each other need not be in continuous communication with each other, unless expressly specified otherwise. In addition, devices or system modules that are in at least general communication with each other may communicate directly or indirectly through one or more intermediaries. Moreover, it is understood that any system components described or named in any embodiment or claimed herein may be grouped or sub-grouped (and accordingly implicitly renamed) in any combination or sub-combination as those skilled in the art can imagine as suitable for the particular application, and still be within the scope and spirit of the claimed embodiments of the present invention. For an example of what this means, if the invention was a controller of a motor and a valve and the embodiments and claims articulated those components as being separately grouped and connected, applying the foregoing would mean that such an invention and claims would also implicitly cover the valve being grouped inside the motor and the controller being a remote controller with no direct physical connection to the motor or internalized valve, as such the claimed invention is contemplated to cover all ways of grouping and/or adding of intermediate components or systems that still substantially achieve the intended result of the invention.

A description of an embodiment with several components in communication with each other does not imply that all such components are required. On the contrary, a variety of optional components is described to illustrate the wide variety of possible embodiments of the present invention.

As is well known to those skilled in the art many careful considerations and compromises typically must be made when designing for the optimal manufacture of a commercial implementation of any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate or interact with each other.

A “computer” may refer to one or more apparatus and/or one or more systems that are capable of accepting a structured input, processing the structured input according to prescribed rules, and producing results of the processing as output. Examples of a computer may include: a computer; a stationary and/or portable computer; a computer having a single processor, multiple processors, or multi-core processors, which may operate in parallel and/or not in parallel; a general purpose computer; a supercomputer; a mainframe; a super mini-computer; a mini-computer; a workstation; a micro-computer; a server; a client; an interactive television; a web appliance; a telecommunications device with internet access; a hybrid combination of a computer and an interactive television; a portable computer; a tablet personal computer (PC); a personal digital assistant (PDA); a portable telephone; application-specific hardware to emulate a computer and/or software, such as, for example, a digital signal processor (DSP), a field-programmable gate array (FPGA), an application specific integrated circuit (ASIC), an application specific instruction-set processor (ASIP), a chip, chips, a system on a chip, or a chip set; a data acquisition device; an optical computer; a quantum computer; a biological computer; and generally, an apparatus that may accept data, process data according to one or more stored software programs, generate results, and typically include input, output, storage, arithmetic, logic, and control units.

Those of skill in the art will appreciate that where appropriate, some embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Where appropriate, embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

“Software” may refer to prescribed rules to operate a computer. Examples of software may include: code segments in one or more computer-readable languages; graphical and/or textual instructions; applets; pre-compiled code; interpreted code; compiled code; and computer programs.

While embodiments herein may be discussed in terms of a processor having a certain number of bit instructions/data, those skilled in the art will know others that may be suitable such as 16 bits, 32 bits, 64 bits, 128s or 256-bit processors or processing, which can usually alternatively be used. Where a specified logical sense is used, the opposite logical sense is also intended to be encompassed.

The example embodiments described herein can be implemented in an operating environment comprising computer-executable instructions (e.g., software) installed on a computer, in hardware, or in a combination of software and hardware. The computer-executable instructions can be written in a computer programming language or can be embodied in firmware logic. If written in a programming language conforming to a recognized standard, such instructions can be executed on a variety of hardware platforms and for interfaces to a variety of operating systems. Although not limited thereto, computer software program code for carrying out operations for aspects of the present invention can be written in any combination of one or more suitable programming languages, including an object oriented programming languages and/or conventional procedural programming languages, and/or programming languages such as, for example, Hyper text Markup Language (HTML), Dynamic HTML, Extensible Markup Language (XML), Extensible Stylesheet Language (XSL), Document Style Semantics and Specification Language (DSSSL), Cascading Style Sheets (CSS), Synchronized Multimedia Integration Language (SMIL), Wireless Markup Language (WML), Java™, Jini™, C, C++, Smalltalk, Perl, UNIX Shell, Visual Basic or Visual Basic Script, Virtual Reality Markup Language (VRML), ColdFusion™ or other compilers, assemblers, interpreters or other computer languages or platforms.

Computer program code for carrying out operations for aspects of the present invention may be written in any combination of one or more programming languages, including an object-oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

A network is a collection of links and nodes (e.g., multiple computers and/or other devices connected together) arranged so that information may be passed from one part of the network to another over multiple links and through various nodes. Examples of networks include the Internet, the public switched telephone network, the global Telex network, computer networks (e.g., an intranet, an extranet, a local-area network, or a wide-area network), wired networks, and wireless networks.

The Internet is a worldwide network of computers and computer networks arranged to allow the easy and robust exchange of information between computer users. Hundreds of millions of people around the world have access to computers connected to the Internet via Internet Service Providers (ISPs). Content providers (e.g., website owners or operators) place multimedia information (e.g., text, graphics, audio, video, animation, and other forms of data) at specific locations on the Internet referred to as webpages. Websites comprise a collection of connected, or otherwise related, webpages. The combination of all the websites and their corresponding webpages on the Internet is generally known as the World Wide Web (WWW) or simply the Web.

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The flowchart and block diagrams in the figures illustrate the architecture, functionality, and operation of possible implementations of systems, methods and computer program products according to various embodiments. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

Further, although process steps, method steps, algorithms or the like may be described in a sequential order, such processes, methods and algorithms may be configured to work in alternate orders. In other words, any sequence or order of steps that may be described does not necessarily indicate a requirement that the steps be performed in that order. The steps of processes described herein may be performed in any order practically. Further, some steps may be performed simultaneously.

It will be readily apparent that the various methods and algorithms described herein may be implemented by, e.g., appropriately programmed general purpose computers and computing devices. Typically, a processor (e.g., a microprocessor) will receive instructions from a memory or like device, and execute those instructions, thereby performing a process defined by those instructions. Further, programs that implement such methods and algorithms may be stored and transmitted using a variety of known media.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article.

The functionality and/or the features of a device may be alternatively embodied by one or more other devices which are not explicitly described as having such functionality/features. Thus, other embodiments of the present invention need not include the device itself.

The term “computer-readable medium” as used herein refers to any medium that participates in providing data (e.g., instructions) which may be read by a computer, a processor or a like device. Such a medium may take many forms, including but not limited to, non-volatile media, volatile media, and transmission media. Non-volatile media include, for example, optical or magnetic disks and other persistent memory. Volatile media include dynamic random-access memory (DRAM), which typically constitutes the main memory. Transmission media include coaxial cables, copper wire and fiber optics, including the wires that comprise a system bus coupled to the processor. Transmission media may include or convey acoustic waves, light waves and electromagnetic emissions, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, removable media, flash memory, a “memory stick”, any other memory chip or cartridge, a carrier wave as described hereinafter, or any other medium from which a computer can read.

Various forms of computer readable media may be involved in carrying sequences of instructions to a processor. For example, sequences of instruction (i) may be delivered from RAM to a processor, (ii) may be carried over a wireless transmission medium, and/or (iii) may be formatted according to numerous formats, standards or protocols, such as Bluetooth, TDMA, CDMA, 3G.

Where databases are described, it will be understood by one of ordinary skill in the art that (i) alternative database structures to those described may be readily employed, (ii) other memory structures besides databases may be readily employed. Any schematic illustrations and accompanying descriptions of any sample databases presented herein are exemplary arrangements for stored representations of information. Any number of other arrangements may be employed besides those suggested by the tables shown. Similarly, any illustrated entries of the databases represent exemplary information only; those skilled in the art will understand that the number and content of the entries can be different from those illustrated herein. Further, despite any depiction of the databases as tables, an object-based model could be used to store and manipulate the data types of the present invention and likewise, object methods or behaviors can be used to implement the processes of the present invention.

A “computer system” may refer to a system having one or more computers, where each computer may include a computer-readable medium embodying software to operate the computer or one or more of its components. Examples of a computer system may include: a distributed computer system for processing information via computer systems linked by a network; two or more computer systems connected together via a network for transmitting and/or receiving information between the computer systems; a computer system including two or more processors within a single computer; and one or more apparatuses and/or one or more systems that may accept data, may process data in accordance with one or more stored software programs, may generate results, and typically may include input, output, storage, arithmetic, logic, and control units.

A “network” may refer to a number of computers and associated devices that may be connected by communication facilities. A network may involve permanent connections such as cables or temporary connections such as those made through telephone or other communication links. A network may further include hard-wired connections (e.g., coaxial cable, twisted pair, optical fiber, waveguides, etc.) and/or wireless connections (e.g., radio frequency waveforms, free-space optical waveforms, acoustic waveforms, etc.). Examples of a network may include: an internet, such as the Internet; an intranet; a local area network (LAN); a wide area network (WAN); and a combination of networks, such as an internet and an intranet.

As used herein, the “client-side” application should be broadly construed to refer to an application, a page associated with that application, or some other resource or function invoked by a client-side request to the application. A “browser” as used herein is not intended to refer to any specific browser (e.g., Internet Explorer, Safari, FireFox, or the like) but should be broadly construed to refer to any client-side rendering engine that can access and display Internet-accessible resources. A “rich” client typically refers to a non-HTTP based client-side application, such as an SSH or CFIS client. Further, while typically the client-server interactions occur using HTTP, this is not a limitation either. The client server interaction may be formatted to conform to the Simple Object Access Protocol (SOAP) and travel over HTTP (over the public Internet), FTP, or any other reliable transport mechanism (such as IBM® MQSeries® technologies and CORBA, for transport over an enterprise intranet) may be used. Any application or functionality described herein may be implemented as native code, by providing hooks into another application, by facilitating use of the mechanism as a plug-in, by linking to the mechanism, and the like.

Exemplary networks may operate with any of a number of protocols, such as Internet protocol (IP), asynchronous transfer mode (ATM), and/or synchronous optical network (SONET), user datagram protocol (UDP), IEEE 802.x, etc.

Embodiments of the present invention may include apparatuses for performing the operations disclosed herein. An apparatus may be specially constructed for the desired purposes, or it may comprise a general-purpose device selectively activated or reconfigured by a program stored in the device.

Embodiments of the invention may also be implemented in one or a combination of hardware, firmware, and software. They may be implemented as instructions stored on a machine-readable medium, which may be read and executed by a computing platform to perform the operations described herein.

More specifically, as will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

In the following description and claims, the terms “computer program medium” and “computer readable medium” may be used to generally refer to media such as, but not limited to, removable storage drives, a hard disk installed in hard disk drive, and the like. These computer program products may provide software to a computer system. Embodiments of the invention may be directed to such computer program products.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, and as may be apparent from the following description and claims, it should be appreciated that throughout the specification descriptions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Additionally, the phrase “configured to” or “operable for” can include generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

In a similar manner, the term “processor” may refer to any device or portion of a device that processes electronic data from registers and/or memory to transform that electronic data into other electronic data that may be stored in registers and/or memory. A “computing platform” may comprise one or more processors.

Embodiments within the scope of the present disclosure may also include tangible and/or non-transitory computer-readable storage media for carrying or having computer-executable instructions or data structures stored thereon. Such non-transitory computer-readable storage media can be any available media that can be accessed by a general purpose or special purpose computer, including the functional design of any special purpose processor as discussed above. By way of example, and not limitation, such non-transitory computer-readable media can include RAM, ROM, EEPROM, CD-ROM or other optical disk storage, magnetic disk storage or other magnetic storage devices, or any other medium which can be used to carry or store desired program code means in the form of computer-executable instructions, data structures, or processor chip design. When information is transferred or provided over a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable media.

While a non-transitory computer readable medium may include, but is not limited to, a hard drive, compact disc, flash memory, volatile memory, random access memory, magnetic memory, optical memory, semiconductor-based memory, phase change memory, periodically refreshed memory, quantum memory, and the like; the non-transitory computer readable medium, however, does not include a pure transitory signal per se; i.e., where the medium itself is transitory.

It is to be understood that any exact measurements/dimensions or particular construction materials indicated herein are solely provided as examples of suitable configurations and are not intended to be limiting in any way. Depending on the needs of the particular application, those skilled in the art will readily recognize, in light of the following teachings, a multiplicity of suitable alternative implementation details.

Some embodiments of the present invention and variations thereof relate to compute-in-memory architecture integrated within 3D stacked memory devices for efficient data processing in artificial intelligence and edge computing environments.

In one embodiment of the present invention, a compute-in-memory (CIM) architecture integrated with a three-dimensional (3D) stacked memory structure is disclosed. The system may incorporate a plurality of vertically stacked memory layers connected through through-silicon vias (TSVs) and a logic layer positioned beneath. The logic layer may perform computation directly within or proximate to the memory array, significantly enabling in-situ matrix-vector or matrix-matrix multiplication and other arithmetic operations. The architecture may reduce data movement between a processor and external memory, achieving low latency and high energy efficiency. The system appreciably supports digital, analog, or hybrid in-memory computing schemes, suitable for artificial intelligence, signal processing, and edge computing applications.

In other embodiments of the disclosed invention introduces a neural processing unit (NPU) architecture that features a high-performance, energy-efficient neural processing architecture employing three-dimensional (3D) memory stacking and compute-in-memory (CIM) techniques. The invention integrates a generally vertically stacked memory layers directly atop a logic die using advanced bonding technologies, including, without limitation, hybrid copper-to-copper bonding and through-silicon vias (TSVs), thereby significantly reducing interconnect distance, power consumption, and latency.

The architecture largely supports multiple stacking configurations, including face-to-face, face-to-back, and back-to-back arrangements, enabling flexible tradeoffs between interconnect density, signal routing, and package integration. High-speed I/O interfaces may be physically isolated from the memory stack to preserve signal integrity and power domain separation. A logic layer at the base of the stack may coordinate computation, data aggregation, and memory access, enabling efficient multiply-accumulate (MAC) operations using stationary dataflow schemes. By retaining weights, feature maps, or partial sums locally during computation, the architecture substantially minimizes memory traffic and considerably overcomes the memory wall limitations of conventional von Neumann systems.

The invention further provides a scalable multi-core NPU interconnected by a Network-on-Chip (NoC), enabling high-bandwidth communication among compute cores and shared system components. A DMA engine with an integrated copy module may facilitate efficient data movement between external memory, stacked memory, and local SRAM. Collectively, the disclosed system achieves substantial improvements in throughput, power efficiency, and scalability, making it particularly suitable for edge AI, embedded inference, and high-performance computing applications requiring dense memory integration and low-latency computation.

In some embodiments of the present invention, 3D memory may be used to shorten the distance and latency of memory access. A copy engine (or part of DMA engine) is configured to copy, the memory between 3D memory and on chip SRAM, with ground of banks to associate. That makes the memory to deal only localization.

In some embodiments of the disclosed invention provides a neural processing unit (NPU) that may include, without limitation:
A 3D-stacked memory module directly integrated with the NPU core for high-bandwidth, low-latency access.
An external memory interface, such as Low-Power Double Data Rate LPDDR (e.g., LPDDR5), for accessing large memory capacity.
A DMA controller that moves data between:
   NPU SRAM and external LPDDR,
   3D-stacked memory and external LPDDR,
   LPDDR and either on-chip memory resource.
A copy engine that substantially transfers data from 3D-stacked memory to the internal SRAM™ to support low-latency computation.
Optional programmable scheduling logic to orchestrate data prefetch, streaming, or reuse between compute cycles. This architecture significantly enables data to be efficiently transferred without CPU intervention, reduces latency in AI workloads, and optimizes memory bandwidth usage across multiple tiers.

The key advantages of 3D integration may be summarized as follows:

Reduced interconnect length, fundamentally minimizes wiring parasitic and interconnect delay, enhancing signal speed, increased interconnect density, which boosts aggregate communication bandwidth between stacked components and integration of heterogeneous technologies and materials, substantially enabling the combination of dissimilar functions such as, without limitation, logic, memory, and sensing within a single compact system.

In some embodiments, true 3D stacked architectures, such as HMC™ or advanced TSV-bonded memory systems, generally place the logic layer directly beneath the stacked memory arrays, enabling shorter signal paths, higher inter-layer bandwidth, and more efficient thermal dissipation. The configuration, to all intents and purposes, allows integration of compute functionality within or adjacent to memory, thereby supporting in-situ arithmetic operations.

In other embodiments, the present invention discloses a high-performance, energy-efficient neural processing architecture employing three-dimensional (3D) memory stacking and compute-in-memory (CIM) techniques. The invention integrates vertically stacked memory layers directly atop a logic die using advanced bonding technologies, including, without limitation, hybrid copper-to-copper bonding and through-silicon vias (TSVs), thereby significantly reducing interconnect distance, power consumption, and latency.

The architecture, for the most part, supports multiple stacking configurations, including, without limitation, face-to-face, face-to-back, and back-to-back arrangements, enabling flexible tradeoffs between interconnect density, signal routing, and package integration. High-speed I/O interfaces may be physically isolated from the memory stack to preserve signal integrity and power domain separation.

A logic layer at the base of the stack may coordinate computation, data aggregation, and memory access, enabling efficient multiply-accumulate (MAC) operations using stationary dataflow schemes. By retaining weights, feature maps, or partial sums locally during computation, the architecture may substantially minimize memory traffic and may significantly overcome the memory wall limitations of conventional von Neumann systems.

The invention may further provide a scalable multi-core NPU interconnected by a Network-on-Chip (NoC), appreciably enabling high-bandwidth communication among compute cores and shared system components. A DMA engine with an integrated copy module may facilitate efficient data movement between external memory, stacked memory, and local SRAM.

Collectively, the disclosed system achieves substantial improvements in throughput, power efficiency, and scalability, making the system particularly suitable for edge AI, embedded inference, and high-performance computing applications requiring dense memory integration and low-latency computation.

### Advantages

Multi-Dimensional Computing with Stationary Dataflows in a 3D-Stacked Architecture:

The disclosed architecture supports multi-dimensional computing for deep learning inference, including but not limited to matrix multiplication, convolution, attention mechanisms, and tensor operations involving multiple dimensions such as, without limitation, batch, channel, spatial, and kernel dimensions.

Each compute operation may be decomposed into nested multi-dimensional loops, where computation may be distributed across vertically stacked memory layers and coordinated by a logic layer disposed at the base of the stack. The logic layer may schedule and orchestrate an execution of multiply-accumulate (MAC) operations by selectively fetching operands from stacked memory and maintaining intermediate results locally.

The high-bandwidth vertical interconnects enabled by TSVs and hybrid bonding may allow data to be accessed concurrently from multiple memory banks across different layers, enabling massive parallelism along multiple tensor dimensions.

Weight Stagnancy (W-Stationary) in 3D Stacks: In a weight-stationary dataflow scheme, weight parameters of a neural network may be retained locally within memory banks or dedicated buffers in the stacked memory layers, as follows:
Weights may be initially fetched from external LPDDR memory and staged into upper stacked DRAM or directly into memory banks adjacent to compute units.
Once placed, the weights may remain stationary and may be reused across multiple compute cycles.
Input feature map data may be streamed vertically through TSVs to the stationary weights for MAC execution.

By keeping weights stationary within the 3D stack, the architecture may eliminate repeated weight fetches from external memory, which typically dominate memory bandwidth and power consumption in deep learning workloads.

Feature Map Stagnancy (F-Stationary) in 3D Stacks: In a feature-map-stationary scheme, blocks of input activations or intermediate feature maps may be retained locally within buffers or SRAM near the compute logic, as follows:
Feature map tiles may be transferred from external memory into stacked DRAM and then into local SRAM using a DMA controller and copy engine.
The feature map data may remain stationary while different weight sets may be streamed from stacked memory layers to the compute units.
The approach may be particularly effective for convolutional and attention layers, where the same input activation may be reused across multiple output channels.

The proximity of stacked memory to the logic layer largely ensures that streaming weights (W) and accessing stationary feature maps (X) incur minimal latency and power overhead.

Partial Sum Stagnancy (PS-Stationary) in 3D Stacks: Partial sum stagnancy may be implemented to optimize the accumulation of intermediate MAC results during multi-dimensional computation, as follows:
Partial sums generated by successive MAC operations may be retained locally within accumulator registers or buffers in the logic layer.
Contributions from weights (W) and feature maps (X) residing in multiple memory banks and layers may be accumulated over multiple cycles.
The partial sum may remain stationary until the final accumulation may be fundamentally completed, after which the result may be written back to stacked or external memory.

By preventing frequent read-modify-write operations of partial sums to external memory, the architecture may drastically reduce memory traffic and improve compute efficiency.

Coordinated Multi-Stagnancy Execution: The architecture supports dynamic selection and combination of weight-stationary, feature-map-stationary, and partial-sum-stationary dataflows depending on workload characteristics, tensor sizes, and memory capacity. The logic layer coordinates:
Which data dimension remains stationary
Which operands may be streamed vertically through TSVs
When to update stationary buffers through DMA or copy operations

The flexibility allows optimal mapping of multi-dimensional workloads onto the 3D-stacked memory hierarchy.

### Advantages of the Disclosed Architecture:

### 1. Elimination of the Memory Wall

by integrating compute logic directly beneath vertically stacked memory and employing stationary dataflows, the architecture dramatically reduces long-distance data movement between compute and memory, overcoming the memory wall inherent in traditional von Neumann systems.

### 2. Superior Energy Efficiency

Stationary data reuse minimizes high-energy memory accesses.
Vertical TSV interconnects consume significantly less power than long horizontal interconnects.
Hybrid bonding reduces parasitic resistance, capacitance, and inductance.

The factors collectively deliver substantially lower energy per inference operation.

### 3. Massive Parallelism and Bandwidth Density

Concurrent access to multiple memory banks across stacked layers enables parallel MAC execution along multiple tensor dimensions.
Sub-10 μm interconnect pitch supports ultra-high bandwidth density without increasing chip footprint.

### 4. Reduced Latency for AI Inference

SRAM and stacked DRAM act as first-level memory sources.
Copy engines prefetch working tiles, overlapping computation with data movement.
Partial sums may be accumulated locally without external memory round-trips.

This results in deterministic, low-latency inference performance.

### 5. Scalability Across Workloads and Systems

The architecture scales from single-core NPUs to multi-core SoCs interconnected via NoC.
Additional stacked memory layers may be added without redesigning the compute logic.
Chip-to-chip scaling may be supported through PCIe® or die-to-die interfaces.
   6. Flexible Support for AI Models. The Architecture Efficiently Supports:
CNNs (convolutional neural networks)
Transformers and attention mechanisms
Large language models (LLMs)
Multi-modal inference workloads

By dynamically selecting the optimal stagnancy scheme, the system adapts to diverse compute patterns.

### 7. Thermal and Signal Integrity Benefits

Hybrid bonding improves vertical heat dissipation paths.
High-speed I/O interfaces may be isolated from memory stacks.
Reduced driver strength requirements improve signal integrity.
   8. Clear Differentiation from HBM and 2.5D Systems. Unlike 2.5D HBM Systems that Rely on Lateral Interposers:
The architecture provides true 3D compute-memory proximity
Enables compute-in-memory semantics
Achieves higher bandwidth per watt and lower latency

### Potential Applications:

The systems and methods disclosed herein may be broadly applicable to computing platforms that require high-throughput, low-latency, and energy-efficient data processing. By tightly integrating compute logic with three-dimensionally stacked memory and employing stationary dataflow mechanisms, the disclosed architecture may be particularly advantageous for applications constrained by memory bandwidth, power consumption, or form factor.

### 1. Edge Artificial Intelligence (AI) and Embedded Inference:

The invention may be well suited for edge AI devices, including smart cameras, industrial sensors, autonomous terminals, and embedded control systems. The reduced data movement enabled by compute-in-memory and 3D-stacked memory may significantly lower power consumption, allowing complex AI inference workloads to be executed locally without reliance on cloud-based resources.

### 2. Autonomous Systems and Robotics

The disclosed architecture may be deployed in autonomous vehicles, drones, robotic platforms, and unmanned systems that require real-time perception, decision-making, and control. Low-latency inference and high energy efficiency may be critical for the systems, particularly in scenarios involving computer vision, sensor fusion, simultaneous localization and mapping (SLAM), and motion planning.

### 3. Smart Healthcare and Medical Devices

The invention may be applicable to medical imaging systems, diagnostic devices, patient monitoring equipment, and wearable healthcare platforms. The ability to process large volumes of sensor and imaging data locally enables faster diagnosis, improved patient privacy, and reduced dependence on remote computing infrastructure. The architecture may be particularly beneficial for edge-based analysis of biosignals, imaging data, and continuous health monitoring streams.

### 4. Industrial Automation and Intelligent Manufacturing

The disclosed system may be used in industrial automation equipment, including machine vision systems, predictive maintenance platforms, and intelligent robotics deployed in manufacturing environments. The high bandwidth density and deterministic latency provided by the architecture support real-time quality inspection, anomaly detection, and closed-loop control systems.

### 5. Data Center Acceleration and High-Performance Computing (HPC)

The invention may be employed as an accelerator in data centers or high-performance computing systems to offload AI inference, recommendation engines, and data analytics workloads. The 3D-stacked architecture provides superior bandwidth-per-watt compared to traditional accelerator designs relying on external memory and interposers, thereby improving data center energy efficiency and scalability.

### 6. Large Language Model (LLM) and Transformer Inference

The architecture may be well suited for inference workloads associated with transformer-based models, including large language models, vision transformers, and multi-modal models. Stationary dataflow schemes effectively reduce repeated accesses to large weight matrices, key-value caches, and intermediate activations, enabling efficient execution of attention mechanisms and long-sequence processing.

### 7. Consumer Electronics and Smart Devices

The disclosed system may be integrated into consumer electronic products such as, without limitation, smartphones, tablets, smart speakers, augmented reality (AR) and virtual reality (VR) devices, and personal assistants. Local execution of AI workloads improves user responsiveness, enhances data privacy, and reduces power consumption.

### 8. Secure and Privacy-Preserving Computing

By enabling local processing of sensitive data, the invention supports applications requiring enhanced data security and privacy, such as, without limitation, biometric authentication, on-device analytics, and confidential data processing. Reduced reliance on external memory transfers and cloud services minimizes data exposure risks.

### 9. Multi-Chip and Heterogeneous Computing Systems

The architecture may be deployed in multi-chip modules and heterogeneous systems that combine CPUs, GPUs, NPUs, and specialized accelerators. The disclosed die-to-die interfaces and NoC-based interconnect enable scalable chip-to-chip communication, supporting modular system design and workload partitioning.

### 10. Telecommunications and Network Infrastructure

The invention may be applied to telecommunications equipment, including base stations, network edge devices, and intelligent routers, where real-time signal processing, traffic analysis, and AI-driven optimization may be required under strict power and latency constraints.

### 11. Defense, Aerospace, and Mission-Critical Systems

The disclosed architecture may be applicable to defense and aerospace systems that require high reliability, real-time processing, and operation under constrained power and thermal budgets. Examples include radar processing, electronic warfare, surveillance systems, and secure communications.

### 12. Research and Scientific Computing

The invention may be used in scientific instruments and research platforms requiring fast, energy-efficient processing of large datasets, such as, without limitation, genomics analysis, climate modeling, and real-time experimental data processing.

By combining 3D-stacked memory, compute-in-memory techniques, stationary dataflows, and scalable interconnects, the disclosed invention may enable a wide range of applications across edge, cloud, and heterogeneous computing environments. The architecture may provide a compelling solution for next-generation AI and data-intensive workloads where performance, power efficiency, and scalability may be paramount.

The present invention will now be described in detail with reference to embodiments thereof as illustrated in the accompanying drawings.

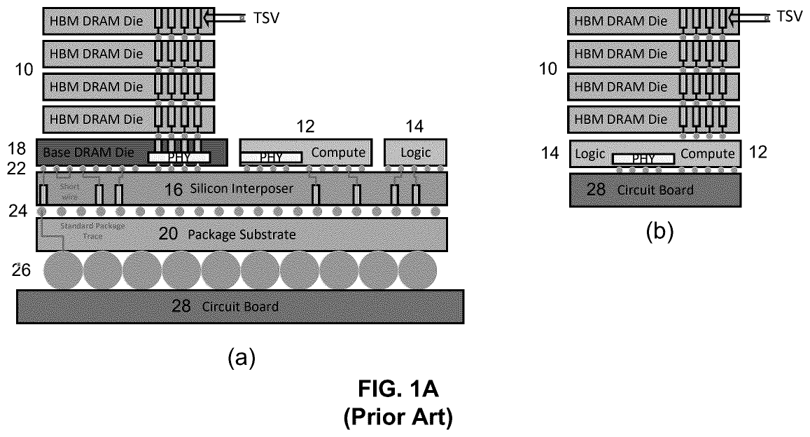

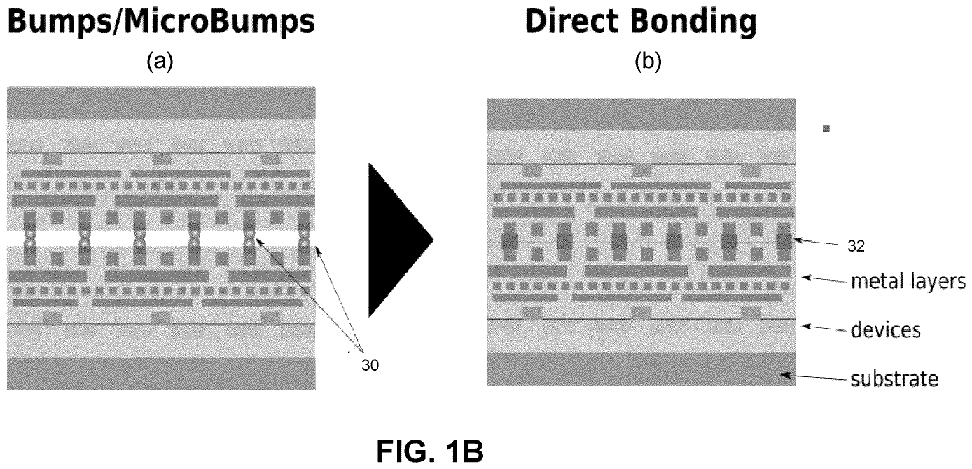

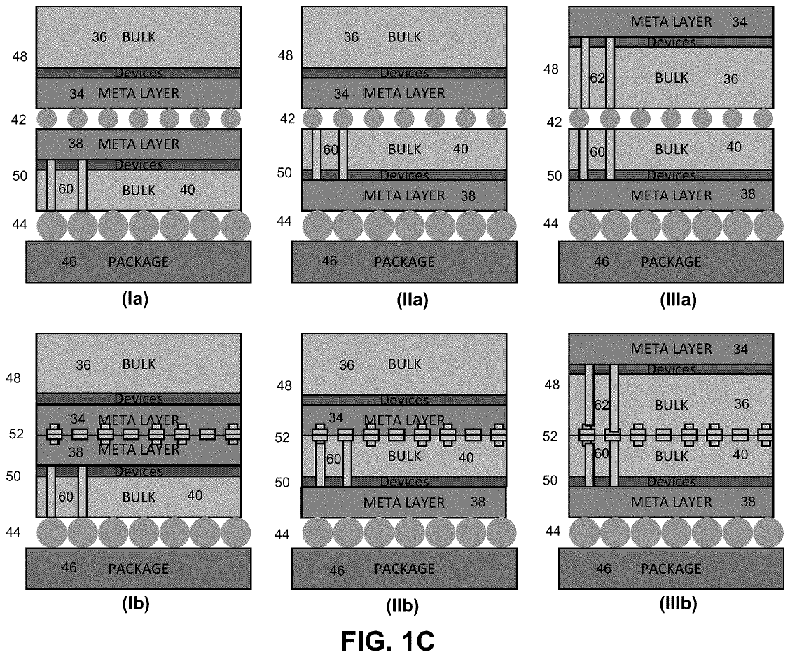

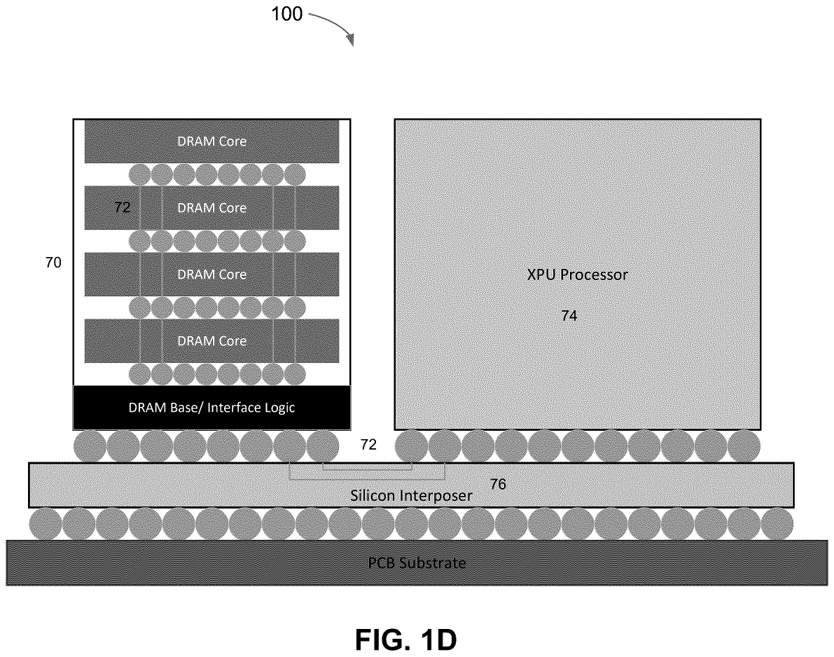

Referring to FIG. 1B, the figure shows a comparison between (a) Bumps/Micro-Bumps 30 and (b) Direct Bonding/Hyper-Bonding 32, in accordance with an embodiment of the present invention. The comparison between (a) Bumps/Micro-Bumps (often solder-capped copper pillars) 30 and (b) Direct Bonding/Hybrid Bonding (often copper-to-copper, or Cu-to-Cu, and dielectric bonding) 32 may be central to advanced 3D integrated circuit (3D IC) packaging. They represent two generations of interconnect technology, primarily differentiated by density, performance, and process complexity. “Direct Bonding” or “Hybrid Bonding” 32 may be generally the newer, higher-performance technology, with “Hyper-Bonding” sometimes used as an industry term for the advanced, extremely fine-pitch implementation of the method.

Here is a detailed comparison in a table format, followed by key explanations:

TABLE 1

| Feature | (a) Bumps/Micro-Bumps | (b) Direct Bonding/Hybrid Bonding |
|---|---|---|
| Interconnect Type | Solder (e.g., SnAg), or | Direct Cu-to-Cu metallic bond and |
| | Copper (Cu) pillar with a | Dielectric (SiO2 or similar) bond. |
| | solder cap. | |
| Connection | Thermo-Compression | Chemical-mechanical bonding, |
| Mechanism | Bonding (TCB) or mass | initiated at room temperature, |
| | reflow of solder. | followed by low-temp anneal. |
| Pitch/Density | Lower Density. Typically >=10 | Highest Density. Sub-10 um pitch |
| | um (common in 2.5D and | may be achievable (<=5 um in |
| | early 3D stacks, e.g., | development). |
| | HBM ™ gen 1-3). | |
| Inter-Die Gap | Large Gap. Requires an | Near Zero Gap. Dielectric bonding |
| | underfill material, creating a | eliminates the need for underfill. |
| | significant about 30 um die- | |
| | to-die standoff. | |
| Electrical | Higher Parasitic (Resistance, | Superior Performance. Low |
| Performance | Inductance, Capacitance - | resistance, inductance, and |
| | RLC). | capacitance due to short, compact |
| | | Cu-to-Cu path. |
| Thermal Performance | Worse. Solder and underfill | Superior Performance. Direct Cu-to- |
| | have lower thermal | Cu and SiO2-to-SiO2 paths offer |
| | conductivity, creating | much better heat conduction, |
| | hotspots. | significantly lowering junction |
| | | temperature. |
| Assembly Flow | Mature. Compatible with | Challenging/Advanced. Requires |
| | existing flip-chip and Over- | extremely tight control over surface |
| | Solder-Mask (OSAT) | planarity (via CMP) and particle |
| | infrastructure. High | cleanliness. Typically, Wafer-to- |
| | throughput for Die-to-Wafer | Wafer (W2W) or high-precision |
| | (D2W) and Die-to-Die | D2W. |
| | (D2D). | |
| Yield/Reliability | More forgiving of minor | Highly Sensitive. Even sub-$1 um |
| | surface defects. Risk of | particle may cause bond defects. |
| | solder joint fatigue. | Excellent long-term reliability |
| | | without organic underfill. |
| Cost | Lower/Established Cost. | Higher Cost (initially) due to |
| | | stringent cleanliness, process control, |
| | | and required equipment. |

### Key Differentiators Explained

Interconnect Density and Pitch—the primary driver for the move to Hybrid Bonding may be pitch scaling as follows.

Micro-Bumps typically struggle to scale below roughly 10 um pitch due to challenges in plating uniformity and the risk of solder bridging/shorting during reflow.

Hybrid Bonding (also known as Direct Bond Interconnect, or DBI®) may avoid solder and uses a metal-metal bond (Cu-to-Cu) embedded in a dielectric layer (SiO2-to-SiO2). This largely enables interconnect pitch down to um or even lower, leading to a massive increase in Input/Output (I/O) count and bandwidth density.

Electrical and Thermal Performance—Hybrid bonding offers significant performance advantages as follows:

Electrical: The direct Cu-to-Cu bond may be a much more compact, pure metallic path than a solder joint. This significantly reduces parasitic effects (R, L, C), which may be critical for high-speed signaling in applications like High Bandwidth Memory (HBM) and High-Performance Computing (HPC).

Thermal: The elimination of the solder cap and organic underfill removes the most thermally resistive layers. The near-zero gaps, and direct dielectric/metal contact may allow heat to dissipate far more efficiently, may be crucial for managing the high-power density of stacked dies.

### Assembly Process and Yield

Micro-Bumps may be assembled using Thermo-Compression Bonding (TCB), where heat and pressure may be applied to melt and solidify the solder caps, forming the joint. The process may be mature but may introduce thermal stress and warpage.

Hybrid Bonding may be a two-step chemical process. The wafers may be first aligned and contacted at room temperature, spontaneously forming a strong dielectric bond. A subsequent low-temperature anneal strengthens the bond and completes the Cu-to-Cu metallic bond. The process requires extreme surface cleanliness and planarity (often achieved with Chemical Mechanical Planarization—CMP), as any microscopic particle may create a void or defect.

Micro-Bumps may be the mature, cost-effective solution for medium-density applications (e.g., 2.5D interposers and first-generation 3D stacks). Direct/Hybrid Bonding may be the advanced, high-performance solution essential for the most demanding 3D ICs (like next-generation HBM, AI accelerators, and chiplet integration) where ultra-high interconnect density and superior electrical/thermal performance may be non-negotiable.

Referring to FIG. 1C, the figure exemplifies various hybrid-bonding scheme including, without limitation, face-to-face (Ia-b), face-to-back (IIa-b) and back-to-back (IIIa-b), in accordance with an embodiment of the present invention. The invention relates to methods and apparatus for high-density, high-performance integration of memory and compute functionalities in a 3D stacked semiconductor package. The die-to-die interconnection may be achieved using Micro-Bumps (e.g., copper pillars with solder caps) 42 (see Ia-IIIa) or Hybrid Bonding (e.g., direct copper-to-copper and dielectric bonding) 52 (see Ib-IIIb). The selection of the bonding scheme may be determined by the required interconnect density and electrical performance.

FIG. 1C further illustrates various 3D stacking configurations for the memory die and the compute die, in accordance with an embodiment of the present invention, as follows:

Configuration 1: Face-to-Face (F2F) Stacking (Ia-b) in the F2F configuration. The active metal layers (faces) 34 38 of both the memory die 48 and the compute die 50 may be oriented towards each other. The Face-to-Face (F2F) arrangement provides the shortest electrical path for high-speed die-to-die (48-50) communication, as metal layers 34 38 of dies 48 50 may be brought into direct bonding proximity with micro-bumps 42 (see Ia) or Hybrid Bonding 52 (see Ib). Several types of suitable hybrid bonding, ranging from specialized materials to unconventional process flows may include:

### 1. Multi-Material Metallic Alloys (Beyond Pure Copper)

While pure Copper (Cu) is the industry standard, it suffers from rapid oxidation and high diffusion rates. “Unusual” methods may involve alloying the bonding pads to control grain growth or improve electromigration resistance.

Cu—Mn (Copper-Manganese) or Cu—Al Alloys: Small percentages of Manganese or Aluminum may create a self-forming barrier layer at the interface.

Nano-Twinned Copper (nt-Cu): Using electroplating parameters to create highly oriented grains. This allows for bonding at significantly lower temperatures because the atomic diffusion occurs faster along the grain boundaries.

### 2. Heterogeneous Dielectric Interfaces

Standard hybrid bonding uses SiO2 or SiCN as the insulating layer. Unusual methods utilize “Low-k” or “High-k” dielectrics to manage parasitic capacitance or thermal dissipation.

Polymer-Metal Hybrid Bonding: Using photosensitive polyimides or BCB (Benzocyclobutene) as the dielectric. This is “unusual” because polymers are compliant, allowing them to absorb the topography of the chip better than rigid oxides.

Air-Gap Hybrid Bonding: Incorporating intentional voids or air-pockets around the metal pillars to reduce the effective dielectric constant (keff), boosting signal speed in high-frequency RF applications.

### 3. All-Cold “Surface Activated” Bonding (SAB)

Most hybrid bonding requires a high-temperature “permanent bond” bake (around 200° C.-400° C.). An unusual and highly valuable variation is SAB, which happens at room temperature.

Plasma/Ion Beam Activation: Using an Argon or Oxygen plasma to “scrub” the surface atoms until they have dangling bonds.

The Benefit: This is crucial for bonding chips with wildly different Coefficients of Thermal Expansion (CTE), such as bonding InP (Indium Phosphide) to Silicon. If you heated them, they would crack; SAB keeps them cool and stable.

4. Direct Bond Interconnect (DBI) with Recessed Features

Standard bonding aims for a perfectly flush surface. An unusual variation involves engineered recess depth control.

Controlled “Dishing”: Intentionally over-polishing the copper so it sits 2-5 nm below the dielectric surface. Upon heating, the copper expands (more than the oxide) to “plug” the gap.

Expansion-Matched Bonding: Designing the metal pillar with a specific geometry (like a “thumbtack” shape) to focus the mechanical pressure precisely at the center of the bond pad, ensuring no edge-voids.

### 5. Liquid-Phase Assisted Hybrid Bonding

While most hybrid bonding is “solid-state,” some advanced methods use a transient liquid phase to bridge the gap.

In—Sn or Ag—Sn Nanopaste Interlayers: A thin layer of Tin (Sn) is applied to the pads. During bonding, the Sn melts and reacts with the Copper to form an Intermetallic Compound (IMC) like Cu6Sn5.

Why it's unusual: It provides the “flow” of a solder bond with the “permanence” and high-melt temperature of a metal bond.

TABLE 2
Comparison Summary

| Method | Material Innovation | Primary Advantage |
|---|---|---|
| SAB Hybrid | Plasma-activated | Room temp; Zero thermal |
| | SiO2/Cu | stress. |
| Polymer Hybrid | Polyimides/BCB | High flexibility; lower |
| | | cost CMP. |
| Alloyed Hybrid | Cu—Mn or nt-Cu | Better reliability; faster |
| | | diffusion. |
| Air-Gap Hybrid | Vacuum/Porous | Ultra-low capacitance for |
| | Dielectrics | 6G/RF. |

External package 46 terminals may be physically distant from the bonded interface. Consequently, to route signals from the stack to external package 46 output pins (which may be generally located on the bottom of the stack), Through-Silicon Vias (TSV) 60 may be implemented in one 50 or both stacked dies 50 48 to bridge the distance through silicon bulk 40. Silicon substrate 40 of Compute die 50 may connect to package 46 with bump 44.

Configuration 2: Face-to-Back (F2B) Stacking (IIa-b) in the F2B configuration. The active metal layer (face) 34 of first die (e.g., top die) 48 may be bonded to a silicon substrate side (back) 40 of second die (e.g., bottom die) 50 with micro-bumps 42 (see IIa) or Hybrid Bonding 52 (see IIb). The signals from active layer 38 of bottom die 50 must traverse the die's silicon bulk 40 using TSVs 60 to reach bonding area 42 on its back side 40, thereby enabling the connection to top die 48. A primary advantage of Face-to-Back (F2B) arrangement (IIa-b) may be that the active layer 38 of bottom die 50 may be oriented towards package substrate 46 via bump 44, facilitating a shorter and simpler connection to the package's external output pins, thereby potentially reducing resistance and capacitance for off-stack signals.

Configuration 3: Back-to-Back (B2B) Stacking (IIIa-b) in the B2B configuration. The silicon substrate sides (backs) 36 40 of both top die 48 and bottom die 50 may be oriented towards the bonding interface micro-bumps 42 (see IIa) or Hybrid Bonding 52 (see IIb). In the Back-to-Back (B2B) arrangement (IIIa-b), active metal layers 34 38 of both top die 48 and bottom die 50 may be positioned distant from bonding area 42 or 52. Therefore, TSVs 60 64 in both dies 48 50 may route respective signals from active layers 34 38 through silicon bulk 36 40 to the inter-die bonding location 42. Similar to F2B configuration (Ha-b), back 40 of bottom die 50, closer to package substrate 46, may provide a relatively direct and simplified routing path to the external output pins.

F2F for High-Performance Logic: Where signal integrity and speed are the primary “Problem-Solution” drivers.
Highest Interconnect Density: Because the bond happens directly between the top metal layers, you don't need to go through the silicon substrate. This allows for the smallest possible “pitch” (distance between connections), often sub-1 um.
Reduced Parasitic Capacitance: Since signals don't have to travel through a thick Through-Silicon Via (TSV), the path is incredibly short. This results in ultra-low latency and lower power consumption.
No TSV Requirement for Signal: You can connect two dies without any TSVs passing through the silicon of the top die, simplifying the initial fabrication of that die.

F2B for Volumetric Scaling: Where memory density or multi-layer integration is the primary driver.
Infinite Scalability: F2B is the only way to create “3D Towers” (multi-die stacks). Because each die has its face pointing up, you can keep adding dies (Die 1 Face to Die 2 Back, Die 2 Face to Die 3 Back, etc.).
Simplified Testing: Since all dies are oriented the same way, standard probe testing can often be performed on the top surface of the stack more easily than in flipped configurations.
Heterogeneous Integration: It is often easier to bond a finished, tested “Known Good Die” (KGD) onto a wafer in an F2B orientation for complex system-in-package designs.

Referring to FIG. 1D, the figure illustrates an exemplary CoWoS packaging configuration 100 in which memory dies 70 may be arranged in a face-to-back stacking configuration, in accordance with an embodiment of the present invention. (HBM) Memory stack 70 may be interconnected through through-silicon vias (TSVs) 72 and may be electrically coupled to the compute and logic die 74 via a silicon interposer 76, enabling high-bandwidth, low-latency data transfer between memory die 70 and compute die 74.

The primary “moat” for CoWoS lies in its ability to bypass the physical limitations of traditional PCB (Printed Circuit Board) traces.

Interconnect Density: Traditional packaging relies on organic substrates with wide trace spacing. CoWoS uses a Silicon Interposer with micro-bumps, allowing for thousands of vertical and horizontal connections at a pitch much finer than standard packaging.

Reduced Latency & Power: Because the distances between the NPU and memory are measured in micrometers rather than centimeters, signal integrity is higher. Lower voltages may be utilized to drive signals, which directly contributes to “low power”.

Form Factor Reduction: By “side-packing” components (like an NPU core and 4 stacks of HBM), the total footprint is significantly smaller than having discrete chips spread across a board.

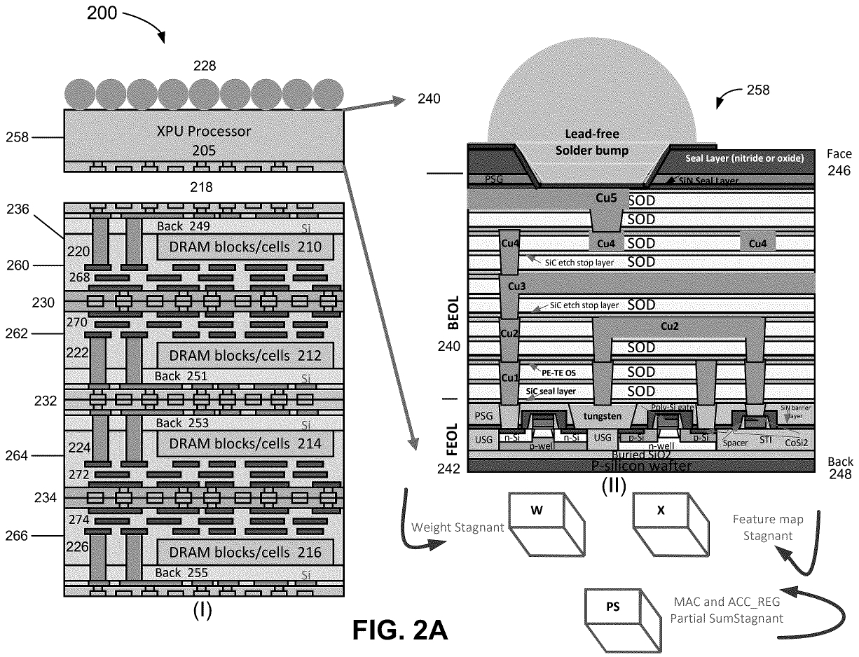

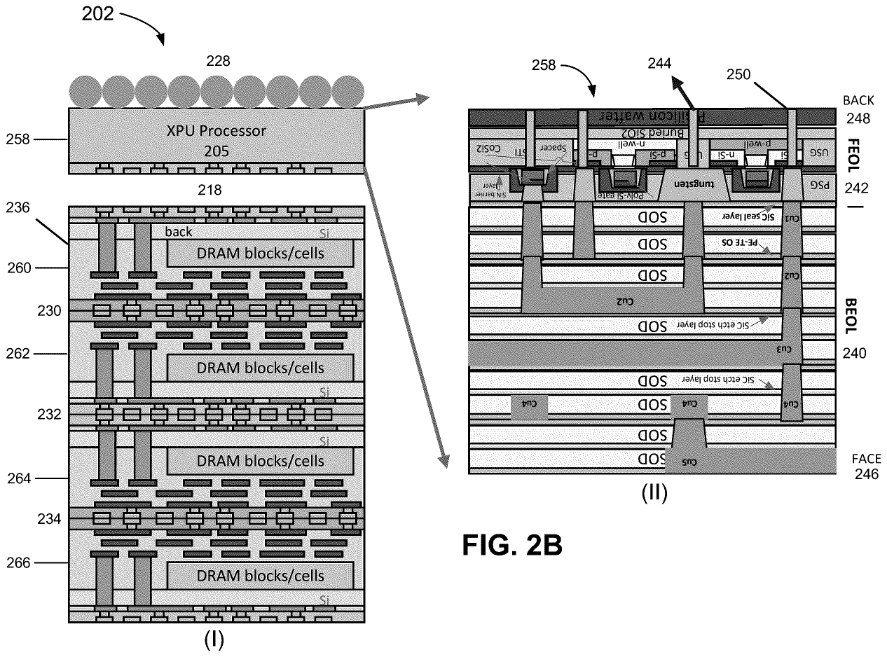

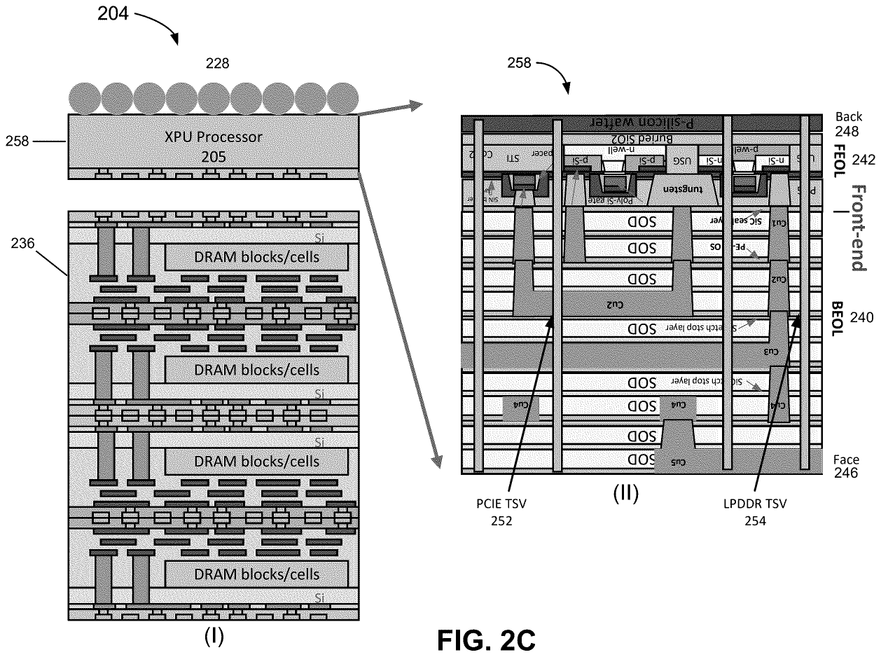

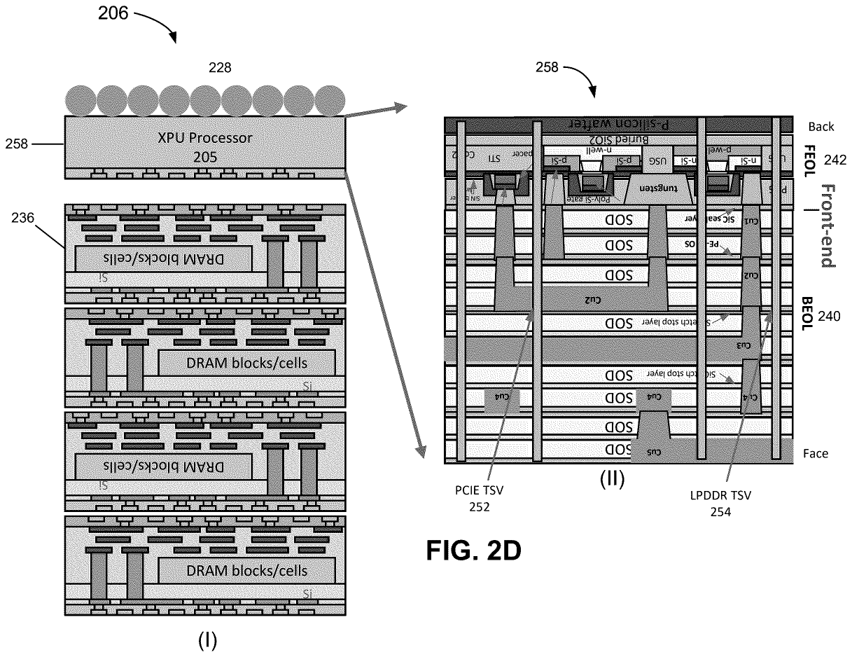

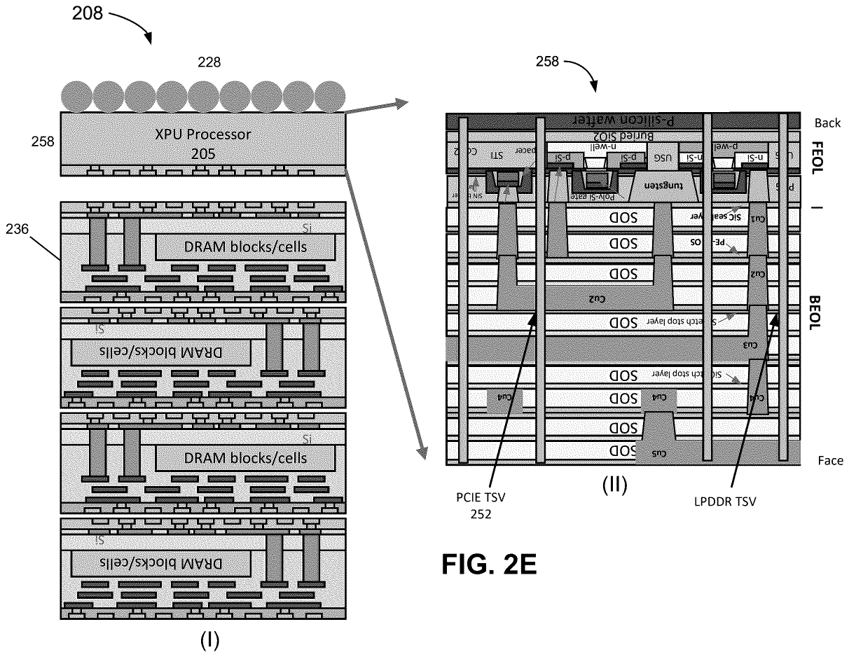

FIG. 2A-2E illustrates an exemplary Cross-Sectional View depicting a cross-section of stack detailing critical functions of Logic Layer 205 (e.g. disposed in Base Die 258) within a 3D-stacked architecture 236 utilizing Hyper-Bonding (high-density, direct Cu-to-Cu) interconnect scheme 218 230 232 234, in accordance with an embodiment of the present invention, as follows:

Functional Interconnect Components—three-dimensional (3D) stack 200 may be constructed upon a Logic Layer 205 (Base Die 258) and comprises:
Vertically Stacked Memory Layers 236: A plurality of memory layers (DRAM blocks/cells) 210-216 may be vertically integrated atop Logic Layer 205.
Through-Silicon Vias (TSVs) 220-226: These form the primary vertical interconnects, passing through the bulk silicon 249-255 of memory layers 260-266 to transport signals, power, and clocking.
Local Inter-Bank Routing: Within each memory layer 260-266, dedicated metal routing (e.g., Cu layers (Cu1-Cu5), as shown in a back-end-of-line (BEOL) section 240 of figure (II)) connects the I/O of each individual memory bank 260-266 to respective TSV interfaces 220-226. This ensures localized data access and transfer capability.
The BEOL (Back-End-of-Line) 240 comprises (not just “wiring”) a layer where the efficiency of a neural network is physically realized.
The BEOL refers to the portion of IC fabrication where the individual devices (transistors, capacitors, etc.) get interconnected with wiring on the wafer. The BEOL with Signal Integrity for Massive Parallelism substantially enables the complex “shuffling” of data required for neural networks. Efficient routing in the BEOL prevents “crosstalk” (interference between wires), which is vital for maintaining the high signal-to-noise ratio needed for superior accuracy.
Logic Layer 205 (Base Die 258) Circuitry: Logic Layer 205 houses essential control and computation circuitry, including:
   Arithmetic and Control Modules: The modules execute computational operations (e.g., MAC units for accumulation) and manage the complex data flow and timing across the stack.
   Interface 228: interfaces, such as, without limitation, the PCIe® and LPDDR shown in the figure (referred to as XPU Processor/Logic), may be integrated to provide external connectivity and system-level communication.

Data Flow and Computation Mechanism—Base Die 205 actively manages data aggregation and computation using the high-bandwidth vertical interconnects. Base Die 205 may comprise, without limitation, a plurality of High-Bandwidth Vertical Interconnects (HBVIs), such as, Direct Bonding wires and Through-Silicon Vias (TSVs), distributed in a high-density array. These HBVIs provide a direct electrical and data-link path between the integrated logic of Base Die 205 and 3D memory Die 236. The arrangement minimizes the lateral travel distance of signals, thereby reducing parasitic capacitance and enabling the real-time aggregation of neural weights with sub-nanosecond latency:
Computation and Accumulation: a) Weights (W) or b) input Feature Maps (X) may be retrieved from the memory layers. The data blocks may be transmitted through the TSVs to the Logic Layer (Base Die) where they may be processed by the embedded arithmetic and control modules.
a) Weights (W): The “Learned Knowledge”
Description: Weights are the learned parameters of a neural network stored after training. They represent the “strength” of connections between neurons.
Significance: In a high-accuracy NPU, the precision of these weights (e.g., FP16, INT8, FP4 or custom sparsity) determines how well the AI “remembers” its training.
Role in Base Die: The Base Die manages the weight-stationary or weight-streaming logic, ensuring that these parameters are fetched through the TSVs just in time for computation to avoid idling.
b) Input Feature Maps (X): The “Input Data”
Description: These are the multi-dimensional arrays (tensors) representing the raw data being processed-such as pixels from a camera or samples from a sensor and the intermediate results of each layer.
Significance: Feature maps are dynamic and high-volume. Maintaining their integrity during high-speed transfer through the TSVs is what prevents “noise” from degrading inference accuracy.
Role in Base Die: The Base Die performs data-reshaping or tiling of these maps to fit the specific hardware constraints of the arithmetic units above.
Base Die 258 functions as a high-speed data-orchestration layer, wherein the Input Feature Maps (X) are dynamically tiled and aligned with corresponding Weights (W) retrieved from the memory layers. By utilizing the High-Bandwidth Vertical Interconnects, the system minimizes the energy-per-bit cost of weight-data movement, facilitating high-precision arithmetic operations with zero-latency synchronization.
Partial Sum (PS) Aggregation: In stationary data flow schemes, Logic Layer (Base Die) 205 coordinates the accumulation of intermediate MAC results (partial sums). The Logic Layer holds partial sum PS in local accumulator registers, allowing for high-speed summation before the final result may be written back or outputted to the memory Die thru High-Bandwidth Vertical Interconnects (HBVIs), such as, Direct Bonding wires and Through-Silicon Vias (TSVs), distributed in a high-density memory array.
High-Density Bonding Implementation (i.e. Hyper-Bonding): Vertical connection 218 between Logic Layer 205 and first memory layer 260, and between subsequent memory layers 210 212 214 216, may be achieved using Hyper-Bonding scheme 230 232 234, for example, without limitation:
   Signal Conductor: Electroplated Copper (Cu) pads or pillars.
   Bond Interface: Direct Cu-to-Cu hybrid bonding, which leverages extremely planarized surfaces (via CMP) and dielectric (SiO2) bonding to achieve ultra-high interconnect density (e.g. pitch roughly less than 20 um) and superior electrical/thermal performance compared to traditional micro-bumps.

Referring to FIG. 2A, the figure illustrates an exemplary back 248 to back 249 (B2B) stacked configuration 200 of compute 205 and memory dies 236 with hybrid bonding 218, in accordance with an embodiment of the present invention. In an embodiment of the present invention, memory dies 260 262 may be arranged in a face 268 to face 270 (F2F) connected pairs of dies 260 262 using hybrid bonding 230 and a face 272 to face 274 (F2F) connected pairs of dies 264 266 using hybrid bonding 234, with each pair of dies 262 264 further interconnected in a back 251 to back 253 (B2B) configuration using hybrid bonding 232. External pins 228 may be routed outward to provide power delivery and to support interfaces such as, without limitation, PCIe®, LPDDR, and other memory and I/O connections.

FIG. 2A further illustrates a heterogeneous 3D integrated circuit (3DIC) assembly. The architecture utilizes Hybrid Bonding (HB), a copper-to-copper direct bonding technique to achieve ultra-high interconnect density without the use of traditional solder bumps.

The configuration demonstrates a “multi-tier” stack where: Memory Dies (260, 262, 264, 266) are vertically integrated. The Face-to-Face (F2F) connections (230, 234) may align the top metal layers (BEOL) of two chips for the shortest possible signal path. Back-to-Back (B2B) connections 218 232 utilize Through-Silicon Vias (TSVs) to pass signals through the silicon bulk to the next pair of dies. The hybrid approach allows Base Die 258 to manage memory access with the latency of on-chip cache but the capacity of external DRAM.

In the context of the NPU computation mechanism, these elements represent the Tensors and the Data Flow:

W (Weights): These 3D blocks represent the static parameters of the neural network. In FIG. 2A, these are stored in the upper memory layers and streamed downward.

X (Input Feature Maps): These represent the incoming data (e.g., image or sensor data). The “3D” nature of the box illustrates the Channel, Height, and Width dimensions of the tensor.

PS (Partial Sums): PS represents the intermediate results of a multiplication (W×X). Because the NPU is high-accuracy, these partial sums are often stored in a higher precision (e.g., 32-bit) than the inputs (e.g., 8-bit) to prevent rounding errors before the final result is accumulated.

Vertical Arrows: These indicate the Unidirectional or Bi-directional Data Movement through the TSVs. Downward (upside down view) typically indicate Weight/Feature fetching; Upward (upside down view) indicate Final Sum storing or status signaling.

Active Base Die as the aggregator of Partial Sums (PS) to reduce data traffic to the upper memory layers.

Hybrid Bonding Die is specifically to maintain the signal integrity of High-Accuracy Weights (W) and Feature Maps X.

The FEOL as a thin layer near the Hybrid Bonding interface for F2F, and the TSVs extending from the FEOL/BEOL through the Silicon Bulk to the Back surface for B2B]

Referring to FIG. 2B, the figure illustrates an exemplary face-to-back (F2B) stacked configuration 202 of compute 205 and memory dies 236, in accordance with an embodiment of the present invention. In an embodiment of the present invention, memory dies 236 may be arranged as face-to-face (F2F) connected pair 260 262 with hybrid bonding 230 and 264 266 with hybrid bonding 234, with each pair 262 264 further interconnected in a back-to-back (B2B) configuration with hybrid bonding 232. External pins 244 may be routed outward with TSV 250, to connect out for PCIE or LPDDR interface, to provide power delivery and to support interfaces such as, without limitation, PCIe®, LPDDR, and other memory and I/O connections.

In semiconductor manufacturing, a “Die” is a sandwich of different layers as follows:

Face 246 is BEOL 240 Side: The Face is defined as the side of the silicon where the metal interconnect layers (Back-End-of-Line or BEOL) are built. This is where the “wiring” lives. Therefore, in any drawing, BEOL 240 and Face 246 must be on the same side because BEOL 240 is the face of the chip.

Back 248 is FEOL 242 Side: The Back is the bulk silicon substrate. Front-End-of-Line (FEOL) 242 represents the actual transistors etched into that silicon. Because the transistors are the first things built on the silicon wafer before the metal layers are added, they sit at the interface between the silicon bulk (Back) and the wiring (Face).

Why they appear “Upside Down” in FIG. 2B: By flipping Base Die 258 (NPU 205) Face-to-Back (F2B) 205 with Memory Die 236, the NPU's high-speed wiring (BEOL 240) is placed in direct contact with the memory stack's interface. This minimizes the distance data must travel from the memory cells to the NPU's arithmetic units.
Use Case: Large Language Models (LLMs) or High-Resolution Image Recognition.
Mechanism: In the F2B interconnection, BEOL 240 (Face 246) of NPU 205 is oriented toward Memory Die stack 236.
Result: The Weights (W) and Feature Maps (X) do not have to travel through the entire thickness of the NPU silicon to reach the logic. They hit the metal “Face” immediately. This reduces Latency and Power Consumption, supporting a “Very Low Power” AI.
Advantage: As shown in FIG. 2B, having the NPU's Face oriented toward the memory allows Back 248 to be dedicated to External Pins 228 and TSVs 252, 254 (see FIG. 2C).
Benefit: This separates “Internal AI Traffic” (NPU to Memory) from “External System Traffic” (NPU to PCIE/CPU). It generally prevents signal interference, which is a major win for Signal Integrity and, by extension, Inference Accuracy.

In the exemplary F2B configuration of FIG. 2B, Base Die 258 is inverted such that its active BEOL layer 240 interfaces with memory stack 236. The orientation provides a ‘Short-Channel’ data path for Weights (W) and Input Feature Maps (X), significantly reducing the power losses associated with vertical data transport. Furthermore, by isolating FEOL 242 toward the substrate side, the assembly achieves superior thermal decoupling, ensuring deterministic execution of high-accuracy AI models without thermal-induced bit-errors.

Referring to FIG. 2C, the figure exemplifies a configuration 204 similar to that shown in FIG. 2B, in accordance with an embodiment of the present invention. In one embodiment, the longer TSVs (e.g. PCIe® TSV 252 and LPDDR TSV 254) generally indicate that the PCIe® or LPDDR blocks may be hardened and electrically coupled to back-end-of-line (BEOL) layers 240, thereby necessitating rerouting of signals from the BEOL layers to backside 248 of semiconductor die 258. As a result, signal paths may be rerouted from BEOL layers 240 to Back (backside) 248 of the semiconductor die.

Referring to FIG. 2C, two polar opposite vertical boundaries of semiconductor die 258 may include:

BEOL Layer 240 (The “Active” Face): This consists of multiple levels of metal interconnects (typically Copper) and dielectric insulators built on top of the transistors. It is the “brain's neural network” where high-speed logic signals for NPU/XPU 205, PCIe, and LPDDR are routed. It is characterized by ultra-fine dimensions and high signal density.

Back (backside) 248 (The “Interface” Surface): Back 248 is the bottom surface of the bulk silicon substrate. In a standard chip, this side is inactive. However, in this configuration, it is used as the landing pad for external connectivity. It is characterized by much larger, ruggedized pads (External Pins 244) that can handle the physical stress of mounting to a PCB.

The “Rerouting” Logic: Because the PCIe/LPDDR logic resides at the BEOL (Face 246) but the exit pins are on Backside 248, TSVs 252, 254 may act as vertical “elevators” that transport the signals through the “dead space” of the silicon substrate.

As illustrated in FIG. 2C, configuration 204 utilizes specialized long-profile TSVs 252, 254 to facilitate electrical communication between the hardened I/O logic in the BEOL 240 and the external interface pins on Backside 248. The bifurcation of signal paths allows for a dedicated, low-interference vertical channel for Weight (W) and Feature Map (X) transfers at the hybrid bonding interface, thereby preserving the signal-to-noise ratio required for high-precision neural computation.

Referring to FIG. 2D, the figure demonstrates an exemplary face-to-face (F2F) stacked configuration 206 of compute 205 and memory dies 236, in accordance with an embodiment of the present invention. In an embodiment of the present invention, the memory dies in each layer may be arranged in a face-to-back (F2B) connected configuration. External pins may be routed outward to provide power delivery and to support interfaces such as, without limitation, PCIe®, LPDDR, and other memory and I/O connections.

The F2F configuration (206) places the BEOL (wiring) of the NPU die (205) in direct physical contact with the BEOL of the first memory die (236) using hybrid bonding.

Maximum “Intelligence-per-Watt” (Power Efficiency)

The Advantage: F2F bonding may offer the shortest possible electrical path between the NPU's arithmetic logic and the stored Weights (W).

Significance: Because the signal doesn't have to travel through the silicon bulk (substrate), the capacitance (C) may be significantly reduced. Since dynamic power is P=alpha*CV\hat{ }2*f, reducing capacitance (C) may allow the NPU to achieve its “very low power” marketing claim while maintaining high clock speeds.

Use Case: Ideal for Battery-Powered Edge AI (e.g., smart glasses or medical implants) where every picojoule saved extends device life by days.

Signal Integrity for “Ultra-High Accuracy”

The Advantage: Traditional TSVs may introduce inductive noise and signal reflections. F2F hybrid bonding uses sub-micron copper-to-copper pads.

Significance: This creates a “clean” data channel with almost zero signal degradation. For high-accuracy AI, this ensures that the Input Feature Maps (X) are not corrupted by thermal noise or crosstalk during transfer.

Use Case: Autonomous Vehicle Vision Systems where a 1% drop in accuracy due to signal noise could mean a difference between identifying a shadow and identifying a pedestrian.

### Extreme Interconnect Density (Bandwidth)

The Advantage: F2F allows for a much tighter “pitch” (spacing between connections) than F2B or B2B. There may be millions of connections per square millimeter.

Significance: This enables the NPU to access the entire memory stack in a “Massively Parallel” fashion. It solves the Memory Wall—the NPU does not have to wait for data, which is essential for real-time, high-accuracy inference.

Use Case: Real-time Generative AI or LLMs at the Edge, where billions of weights must be accessed simultaneously without a massive power drain.

F2F stacked configuration 206 of FIG. 2D facilitates an ultra-dense compute-to-memory interface characterized by the direct fusion of the BEOL layers of Base Die 205 and Memory Die 236. The arrangement eliminates the parasitic RC delay inherent in through-silicon transport, thereby enabling the deterministic transfer of high-precision Weights (W) at a power-per-bit efficiency unattainable in non-F2F architectures. The structural synergy is a primary driver of the system's high-accuracy inference capabilities under strict power constraints.

Referring to FIG. 2E, the figure illustrates an exemplary face-to-back stacked configuration 208 of compute 205 and memory dies 236, in accordance with an embodiment of the present invention. In an embodiment of the present invention, the memory dies in each layer may be arranged in a face-to-back connected configuration. External pins may be routed outward to provide power delivery and to support interfaces such as, without limitation, PCIe®, LPDDR, and other memory and I/O connections.

In the arrangement, Base Die 205 is oriented with the Face (BEOL) toward the Back of the first Memory Die. A “staircase” or “shingled” effect may be created where every die in the stack is oriented in the same direction.

### “Infinite” Vertical Scalability

The Advantage: Because every die is oriented Face-to-Back, the architecture becomes modular. Four (4), 8, 16, or 32 layers of memory may be added without changing the routing logic.

Significance: For the high-accuracy NPU, massive datasets (like a giant localized database for a private LLM) may be supported simply by stacking more identical memory dies.

Use Case: Edge Servers or On-Device LLMs where the model size might grow over time, requiring a hardware architecture that is “future-proof” through simple vertical expansion.

### Simplified Global Clock Distribution

The Advantage: Since every die is oriented the same way, the TSVs for the clock signal and power delivery are identical for every layer.

Significance: This reduces “Clock Skew” (where the signal reaches one part of the chip later than another). For a low-power NPU, a perfectly synchronized clock means you don't have to “over-voltage” the chip to compensate for timing delays, directly contributing to a Low Power structure.

Use Case: High-Speed Signal Processing (like 6G base stations or satellite AI) where nanosecond-level synchronization is required to process incoming data accurately.

F2B configuration 208 provides a homogenous stacking environment wherein Base Die 205 and subsequent Memory Dies 236 share a common vertical orientation. This uniformity enables a standardized TSV architecture for the distribution of the Global Clock and Power Delivery Network (PDN). By utilizing the silicon substrate of each layer as an intermediate thermal buffer, the configuration prevents localized thermal-induced bit-errors, thereby safeguarding the integrity of the High-Accuracy NPU computations during sustained high-load inference operations.

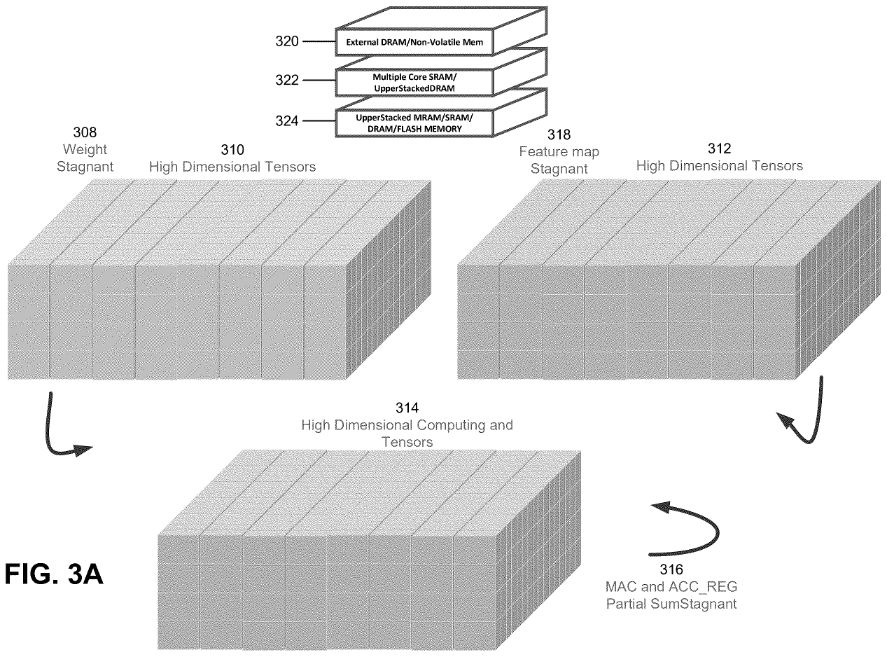

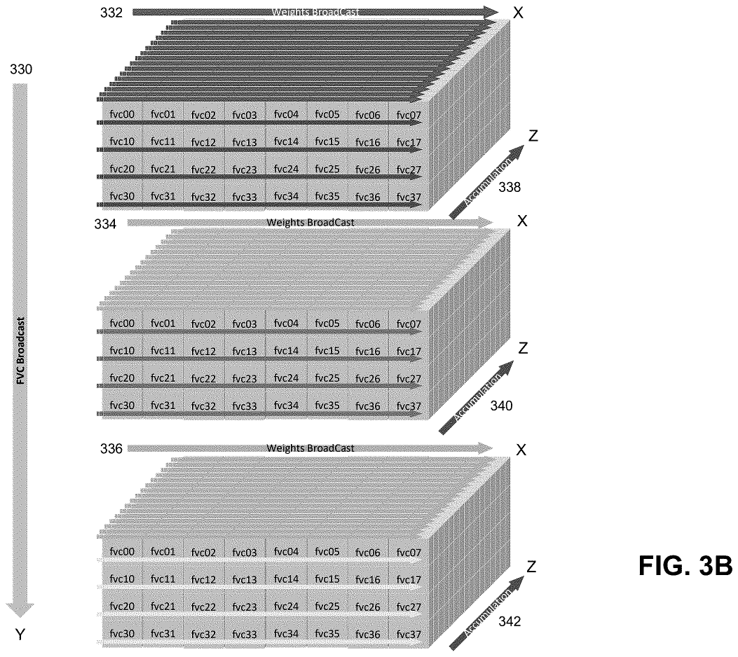

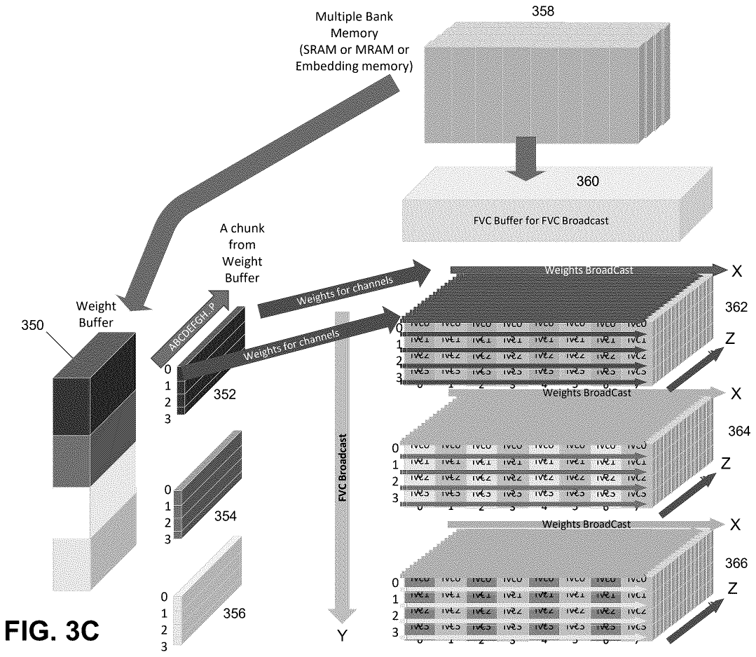

FIG. 3A illustrates an exemplary Multi-Dimensional Tensor Descriptor and Hierarchical Execution Model, in accordance with an embodiment of the present invention. In an embodiment of the present invention, the disclosed architecture may employ a programmable multi-dimensional tensor descriptor 310 312 314 to define data access and execution behavior for compute operations. Each tensor 310 312 314 may be represented as a collection of memory chunks, wherein each chunk corresponds to a contiguous block of data (e.g. Weight 308, Feature map 318) stored in a particular memory region 310 312. The tensor descriptor supports up to eight (8) independent dimensions, each corresponding to a loop variable analogous to nested loop indices (e.g., i, j, k, l, m, n, o, p). Each dimension may be characterized by:
A loop count defining the number of iterations
A memory stride defining the address offset between successive iterations
A base address identifying the starting location of the tensor in memory

The multi-dimensional tensor descriptor encapsulates all loop parameters within a single instruction or command, thereby eliminating the need for explicit software-managed nested loops. During execution, the hardware iterates through the multi-dimensional space by automatically generating memory addresses and execution schedules based on the descriptor parameters.

The same multi-dimensional descriptor mechanism may be applied uniformly to:
Weight tensors 308
Feature map tensors (input and activation data) 318
° ALU or MAC execution sequences 316
Result output

Each of the entities may be associated with its own independent set of loop dimensions, allowing different iteration spaces for weights 308, feature maps 318, and partial sum accumulation 316. The hardware execution engine synchronizes the descriptors to ensure correct alignment of operands across corresponding loop dimensions.

The unified approach enables flexible mapping of high-dimensional tensor operations, including convolutions, matrix multiplications, attention mechanisms, and tensor contractions, without modifying the instruction format.

Each fetch operation retrieves a chunk of data, rather than a single scalar element. A chunk may include multiple tensor elements arranged contiguously in memory and sized to match the data width of the ALU, vector unit, or MAC array. Chunk-based execution provides:
Improved memory bandwidth utilization
Amortized address generation overhead
Efficient vector and tensor execution

The chunk size may be statically configured or dynamically selected based on the target memory hierarchy and compute unit.

The architecture defines a hierarchical, multi-dimensional memory space (Hierarchical Memory Dimension Model) in which each tensor dimension may be mapped to a different memory level. The memory hierarchy may include, but not limited to:
1. Local Memory Near the ALU
   MRAM, SRAM, register files, or other low-latency memory
   Used for stationary data such as, without limitation, partial sums or frequently reused operands
2. Upper-Level Stacked Memory
   3D-stacked DRAM or embedded memory layers
   Provides high bandwidth and low vertical access latency
3. Neighbor-Core Memory
   Memory resources accessible via on-chip NoC
   Enables inter-core data sharing and workload partitioning
4. External Memory
   Off-chip DRAM (e.g., LPDDR, DDR, HBM)
   Used for bulk tensor storage and model parameters
5. External Storage or Connected Systems
   SSDs, network-attached storage, or remote computing systems
   Supports streaming of large models or datasets

Each memory level may be treated as an independent dimension within the execution model, allowing tensor tiles to be progressively staged closer to the compute units as execution advances through the loop hierarchy.

A synchronization scheme (Synchronized Multi-Dimensional Execution and Data Movement) may be provided to coordinate execution across multiple tensor descriptors and memory levels. Synchronization points may be defined at:
Loop boundaries
Chunk completion events
Partial sum accumulation completion
Memory transfer completion via DMA or copy engines

The synchronization broadly ensures correctness when data dependencies exist across different tensor dimensions, memory hierarchies, or compute cores. The synchronization mechanism effectively enables overlapping of data movement and computation, thereby maximizing hardware utilization.

### Advantages of the Descriptor-Based Multi-Dimensional Model:

By encoding complex multi-dimensional loop structures into a compact hardware descriptor, the disclosed architecture:
Reduces instruction overhead and software complexity
Enables deterministic, hardware-managed execution
Supports arbitrary tensor dimensionality up to eight dimensions
Seamlessly integrates compute and hierarchical memory access
Scales across single-core, multi-core, and multi-chip systems

The disclosed multi-dimensional tensor descriptor mainly provides a unified and scalable mechanism for orchestrating high-dimensional tensor computation across a hierarchical memory system. By treating each tensor dimension as an implicit loop and each memory access as a chunk-based operation, the architecture appreciably achieves high efficiency, flexibility, and scalability for modern AI and data-intensive workloads.

FIG. 3B illustrates an exemplary Directional Broadcast and Reduction Across Three-Dimensional Compute Space, in accordance with an embodiment of the present invention. In one embodiment of the present invention, the disclosed architecture operates on chunk-based three-dimensional (3D) tensors, including, without limitation, a chunk of a 3D feature map and a chunk of a corresponding weight tensor. Each chunk may represent a contiguous block of data mapped to the execution granularity of the compute array. The execution model defines three orthogonal logical directions, denoted as X, Y, and Z, corresponding to distinct dimensions of data movement and computation within the processing fabric.

Referring to FIG. 3A and FIG. 3B, the architecture employs a Tri-Level Hierarchical Memory System 320 322 324 orchestrated by the Descriptor-Based Model to generally ensure that the NPU does not “starve” for data. The memory system may comprise, without limitation:

### 1. External System Memory (DRAM/Non-Volatile) 320

Significance: This is the “Long-Term Memory.” External System Memory (DRAM/Non-Volatile) 320 may store the System OS, the full library of high-accuracy AI models (e.g., one for vision, one for speech), and massive datasets.

Role in High Accuracy: By supporting Non-Volatile memory here, the system can perform Instant-On AI inference. The high-precision weights are preserved even during power-off states, allowing for a “Low Power” standby mode that wakes up into a high-accuracy state in milliseconds.

Function: Acts as the primary reservoir for Weights (W) and Feature Maps (X) before they are “tiled” into the faster, more local memory layers.

### 2. On-Chip Core Memory (SRAM/Embedded MRAM) 322.

Significance: This is the “Active Workspace.” It is located within the multiple compute cores of the Base Die.

Role in Low Power: By using Embedded MRAM (eMRAM), you achieve the density of DRAM with the speed of SRAM, but with near-zero leakage power. This is the “secret sauce” for very low power consumption.

Function: On-Chip Core Memory (SRAM/Embedded MRAM) 322 holds the “current tile” of the tensor. The Hardware Descriptor manages the flow from External System Memory (DRAM/Non-Volatile) 320 to On-Chip Core Memory (SRAM/Embedded MRAM) 322, ensuring that the compute cores always have the next set of data ready, eliminating the energy waste of idle cycles.

### 3. Upper Stacking Memory (3D SRAM/DRAM/MRAM/FLASH MEMORY) 324.

Significance: This is the “High-Bandwidth Cache.” Because it is vertically stacked (using the CoWoS or F2F/F2B hybrid bonding discussed earlier), Upper Stacking Memory (3D SRAM/DRAM/MRAM/FLASH MEMORY) 324 provides a massive “data pipe” directly to the NPU logic.

Role in Multi-Chip/Multi-Core Scaling: This layer acts as the Synchronized Buffer. When scaling across multiple chips, Upper Stacking Memory (3D SRAM/DRAM/MRAM/FLASH MEMORY) 324 serves as a shared memory space where Partial Sums (PS) from different chips or cores may be aggregated.

Function: Memory 324 allows the system to support 8D Tensor dimensionality by providing enough high-speed buffer space to hold complex, multi-dimensional loop intermediate results without hitting the “power-hungry” External System Memory (DRAM/Non-Volatile) 320.

### Feature Map Broadcast in the Y Direction 330:

A chunk of the 3D feature map may be broadcast along y direction 330 to multiple compute elements. The broadcast operation enables the same feature map data to be consumed concurrently by multiple processing units, thereby maximizing reuse of activation data across parallel weight applications. The broadcast mechanism eliminates redundant memory fetches and reduces interconnect traffic, particularly for convolutional and tensor multiplication workloads where the same feature map values may be reused across multiple output channels or filters.

### Weight Broadcast in the X Direction 332 334 336:

A chunk of the weight tensor may be broadcast along x direction 332 334 336 to a plurality of compute elements. The broadcasted weight chunk may be applied to multiple feature map chunks received along the y direction, enabling parallel computation across different spatial or channel dimensions. By maintaining weight chunks stationary or semi-stationary within the compute fabric while broadcasting them along the x direction, the architecture reduces repeated weight access from higher-level memory.

### Summation and Reduction in the Z Direction 338 340 342:

Multiply, accumulate operations may be performed at the intersection of the x and y broadcast paths. Partial products generated by the operations may be accumulated along the z direction 338 340 342, which represents the reduction dimension. The summation operation aggregates partial sums across multiple compute cycles, tensor dimensions, or memory layers, resulting in a final accumulated output value. Partial sums may remain stationary within local accumulators until the reduction operation may be complete, after which the result may be written back to memory.

Orthogonal Dataflow and Execution Efficiency:

By orthogonally assigning 1) Feature map broadcasts to the y direction 330, 2) Weight broadcasts to the x direction 332 334 336, and 3) Accumulation to the z direction 338 340 342, the architecture achieves a balanced and highly efficient dataflow. The directional separation enables concurrent data reuse, minimizes memory bandwidth consumption, and supports scalable parallelism across the compute fabric.

The described directional broadcast and reduction model may be applicable to convolutional neural networks, matrix multiplication, attention mechanisms, and other tensor-based computations requiring high data reuse and efficient accumulation.

FIG. 3C illustrates an exemplary Stationary Buffer Architecture with Directional Broadcast and Partial-Sum Accumulation, in accordance with an embodiment of the present invention. In addition to the directional broadcast and summation mechanisms described with respect to the X, Y, and Z dimensions, the disclosed architecture further incorporates a set of stationary (stagnant) buffers to minimize data movement and reduce power consumption during tensor computation as follows:

### Stationary Weight Buffer 350:

The architecture may include, without limitation, a stationary weight buffer 350 disposed proximate to the compute elements or ALU array. A chunk of a weight tensor may be loaded into the stationary weight buffer 350 from a higher-level memory 358, such as, without limitation, stacked memory or external DRAM, and retained locally for reuse across multiple compute cycles. Once resident in stationary weight buffer 350:
The weight chunk may be broadcast along the X direction to multiple compute elements.
The same weight chunk may be reused across multiple feature map chunks without being re-fetched from higher-level memory 358.
Memory access frequency and interconnect traffic associated with weight parameters may be substantially reduced.

Stationary Feature Map Buffer 360:

Similarly, the architecture may include, without limitation, a stationary feature map buffer 360 configured to store a chunk of a feature map tensor locally near the compute fabric. Feature map chunks may be:
Loaded into the stationary feature map buffer via DMA or copy engines
Broadcast along the Y direction to multiple compute elements
Retained locally while multiple weight chunks may be applied

The feature-map-stationary behavior reduces repeated access to stacked or external memory and enables high data reuse for convolutional and tensor operations.

Partial-Sum Stationary Accumulator Buffer 362 364 366:

The architecture may further include one or more partial-sum stationary accumulator buffers 362 364 366 configured to store intermediate results generated by multiply-accumulate operations. Partial sums:
May be generated from interactions between broadcast weight chunks and feature map chunks.
May be accumulated along the Z direction, representing the reduction dimension.
Remain resident in the accumulator buffers while accumulation proceeds across multiple compute cycles.
May be written back to memory only after completion of the summation operation.

By keeping partial sums stationary, the architecture avoids repeated read-modify-write operations to external or stacked memory, which may be typically expensive in terms of latency and power.

Coordinated Chunk-Based Stationary Dataflow:

Stationary weight buffer 350, stationary feature map buffer 360, and partial-weights buffer 352 354 356 may operate in a coordinated manner under control of the multi-dimensional tensor descriptor and synchronization scheme. At runtime:
A chunk of a tensor may be mapped to a corresponding stationary buffer
Remaining tensor chunks may be streamed through the compute fabric via directional broadcast
Accumulation proceeds locally until a synchronization point or chunk-completion condition may be satisfied

The coordinated, chunk-based stationary dataflow may enable flexible execution modes in which weight chunks, feature map chunks, or partial-sum chunks may be selectively retained in local buffers based on workload characteristics and memory availability.

### Power and Performance Advantages:

By retaining tensor chunks in stationary buffers and minimizing transfers between compute units and higher-level memory:
Dynamic power consumption may be significantly reduced
Interconnect utilization may be minimized
Compute units experience fewer stalls due to memory latency

The combination of chunk-based stationary buffers and directional broadcast enables high arithmetic intensity and sustained utilization of compute resources.

The disclosed architecture integrates directional X/Y/Z broadcast with stationary buffers for chunks of weight tensors, chunks of feature map tensors, and chunks of partial sums. The chunk-based stationary execution model substantially reduces data movement, lowers power consumption, and improves performance efficiency, making the architecture particularly suitable for energy-constrained and high-throughput AI inference applications.

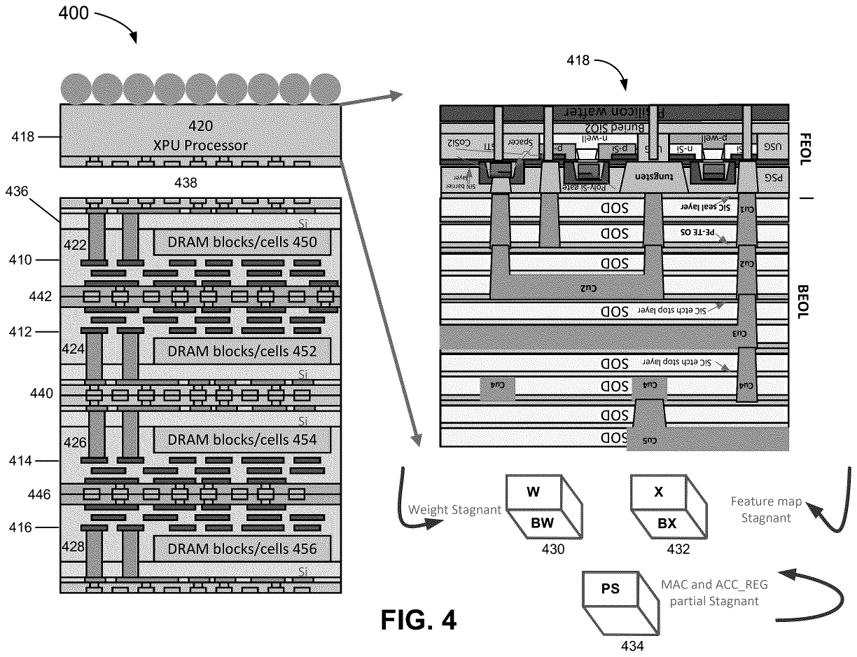

FIG. 4 illustrates an exemplary 3D Stack Architecture 400 in a compute-in-memory device, in accordance with an embodiment of the present invention. Compute-in-memory device comprising, without limitation:
A plurality of memory layers 410 412 414 416 vertically stacked.
A logic layer 420 (e.g. XPU Processor) disposed at a base die 418.
Through-silicon vias (TSVs) 422 424 426 428 forming vertical interconnects among memory layers 410 412 414 416; and
Optional heat-dissipation and interface layers for thermal management and external connectivity.
Each memory layer 410 412 414 416 may include, without limitation, a plurality of memory banks 450 452 454 456 capable of performing localized computations.
Logic layer 420 coordinates computational operations and manages data aggregation across layers.

### Multiply-Accumulate (MAC) Operations in 3D-Stacked Base Layer:

The Multiply-Accumulate (MAC) operations within the 3D-stacked architecture 400, particularly the stationary data flows which may be crucial for the high-energy efficiency of Processing-in-Memory (PIM) or Compute-in-Memory (CIM) systems.

### 1. MAC Functionality in Base Layer 418:

The MAC operation, result=Σᵢ(Wᵢ*Xᵢ), may be the fundamental calculation for deep learning (DL) inference. In the architecture:
Localization: The computational capability may be distributed across base layers 418, often situated near memory banks 450 452 454 456 in the memory layer 410, 412, 414, 416, allowing the computation to be performed in situ where the data may be stored.
Parallelism: Fetching from memory banks 450 452 454 456 and execute MAC operations in parallel on local data in base layer 418, exploiting the massive internal bandwidth provided by Through-Silicon Vias (TSVs) 422 424 426 428.

### 2. Stationary Data Flows for Efficiency:

To mitigate the “memory wall” bottleneck, the high energy and latency cost of data movement between memory 410 412 414 416 and a distant logic unit 418 the design employs specific data reuse or stationary schemes: Within logic unit 418, there are:

### A. Weight Stagnancy (W-Stationary):

Description: Weights (W) 430 may be the parameters of the neural network (e.g., filter kernels in a Convolutional Neural Network). In a W-Stationary flow, the weights (W) may be fetched from the memory bank (or may be already programmed in the memory cells, such as, without limitation, in analog CIM with Resistive RAM) and reused multiple times against different input feature map data (X) 432.
Mechanism in 3D Stack: The weights may be stored within the local memory bank 430 which copy from a specific layer among 450, 452, 454 or 456. They remain “stagnant” (or stationary) in the computation unit (MAC engine) 434 while successive blocks of the input feature map data (X) 432 may be streamed to that unit. This significantly reduces the power consumed by repeated weight reads, which typically comprise the majority of memory accesses in DL inference.

### B. Feature Map Stagnancy (F/I-Stationary):

Description: Feature maps (X) 432 may be the input data (or activations/intermediate results). In an F-Stationary flow, an input feature map block 432 may be loaded once into the MAC engine 434 and reused multiple times against different sets of weights (W) 430.
Mechanism in 3D Stack: A block of input data may be fetched from one memory bank among 450,452,454, and 456 and held in a local register/buffer 432 near the MAC unit 434. The weights for different output channels or subsequent layers may be streamed to the stationary weight block 430. This may be highly effective in layers where the same input data may be convolved or multiplied by many different kernels.

### C. Partial Sum Stagnancy (P-Stationary):

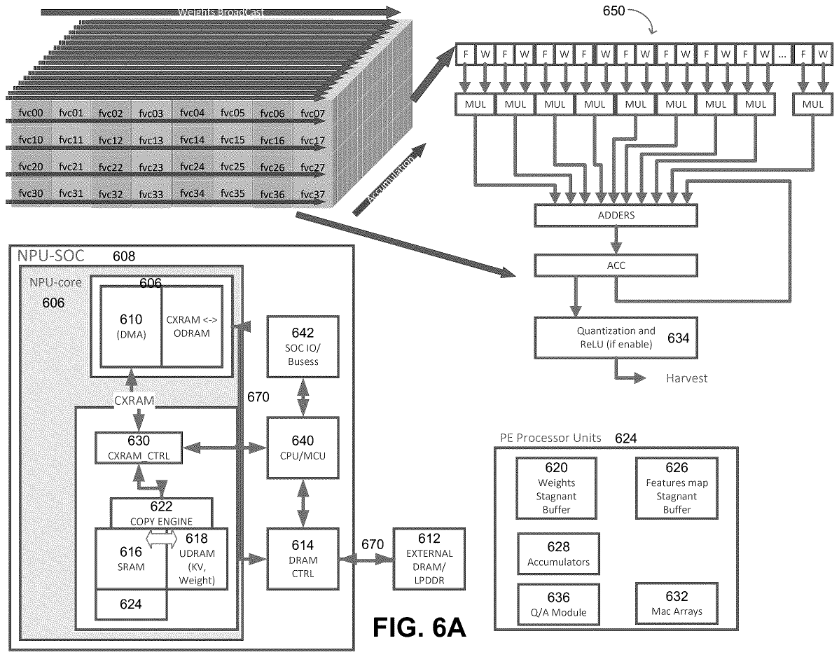

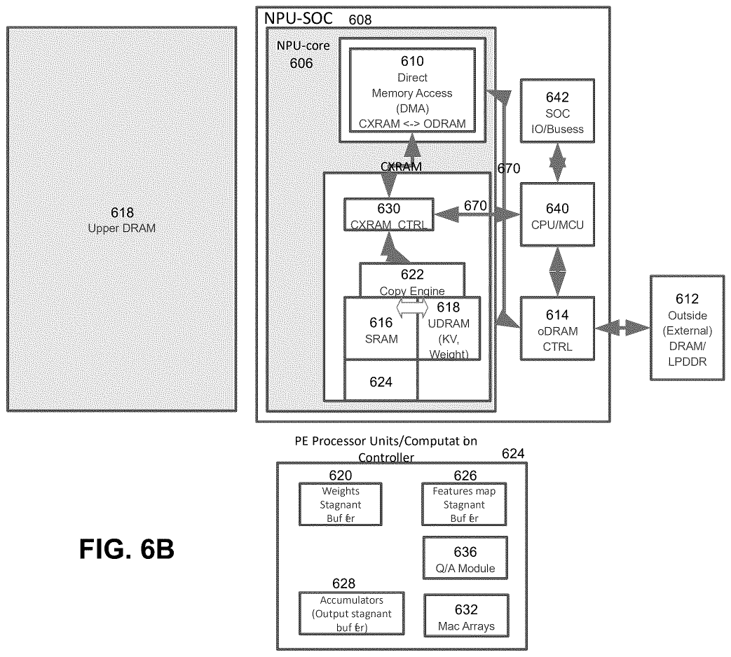

Description: Partial sum (PS) 434 may be the intermediate accumulation, result=Σᵢ(Wᵢ*Xᵢ) before the final accumulation may be complete. In a P-Stationary flow, partial sum 434 may be held locally and repeatedly updated by new MAC results until the final output may be generated.
The Partial Sum Stagnancy (P-Stationary) scheme may be implemented to optimize the aggregation of intermediate results within the 3D-stacked architecture, thereby minimizing costly data movement.
A single final output element, such as, without limitation, a feature map value, often necessitates the accumulation of contributions generated over multiple cycles of Multiply-Accumulate (MAC) operations. The operations may draw their input data (weights and feature maps) from multiple distinct memory banks 450 452 454 456 located across one or more vertically stacked memory layers 410 412 414 416.
The architecture incorporates local control logic, specifically within Base Die 418 (Logic Layer 420), which coordinates the final summation via an accumulation tree 650 (see FIG. 6A). The MAC operation's input operands (weights W and feature maps X) may be drawn from respective Stagnant Buffers (BW and BX), ensuring data reuse and reducing memory fetches.
The intermediate result, known as the Partial Sum (PS), may be held in a dedicated, high-speed accumulator register or buffer within Logic Layer 420 (Base Die 418). The Partial Sum (PS) remains stagnant at Base Die 418 while multiple cycles of MAC results may be accumulated onto it until it reaches to the final result.
The mechanism may be critical as it drastically minimizes the overall memory traffic by preventing the large, frequently updated Partial Sum data from being moved repeatedly between the distributed compute units 418 and the main memory storage 410, 412, 414, 416.

The utilization of the stationary schemes (especially W-Stationary, F-Stationery and PS-Stationary enabled by the TSVs and logic layer) may be critical for achieving the substantial energy efficiency and throughput advantages of 3D-stacked CIM architectures over traditional von Neumann designs.

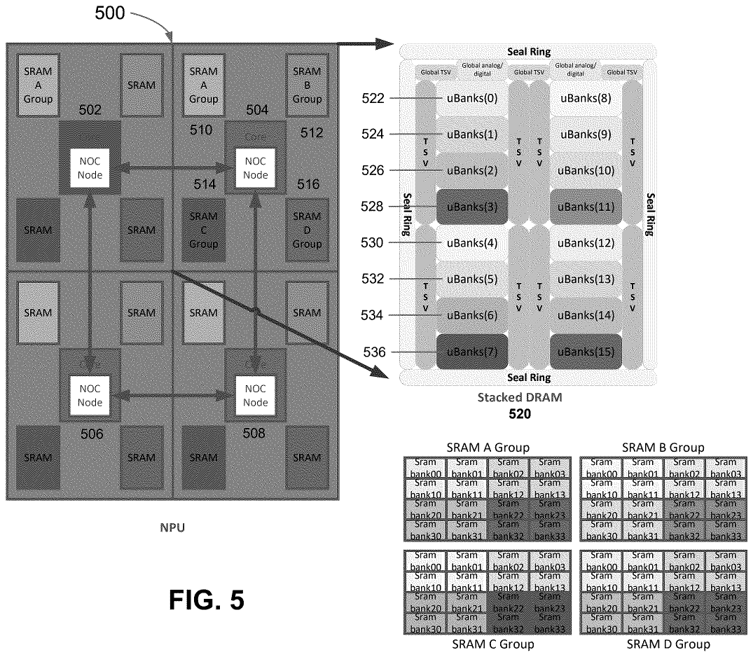

FIG. 5 illustrates an exemplary 4-core NPU architecture 500 in which all cores 502 504 506 508 may be interconnected through a Network-on-Chip (NoC), in accordance with an embodiment of the present invention. In one embodiment of the present invention, each core (e.g. 504) may contain four (4) groups of SRAM 510 512 514 516. In a 3D-stacked configuration, a DRAM die may be placed directly above the NPU. The diagram on the right shows how a DRAM unit stack may be aligned above an individual core. Data transfers may occur either from stacked DRAM 520 to the NPU's local SRAM 510 512 514 516 or from the NPU's SRAM 510 512 514 516 back to stacked DRAM 520. Each DRAM uBank (e.g. uBanks(0) 522) may be paired with local SRAM bank 510 to fundamentally ensure that data movement stays as short and localized as possible, minimizing wire length, logic complexity, and power consumption.

### Core-to-DRAM Association Mapping Example

Associated DRAM uBank 0 522→SRAM Group A 510: bank00, bank01, bank10, bank11
Associated DRAM uBank 1 524→SRAM Group A 510: bank02, bank03, bank12, bank13
Associated DRAM uBank 2 526→SRAM Group A 510: bank20, bank21, bank30, bank31
Associated DRAM uBank 3 528→SRAM Group A 510: bank22, bank23, bank32, bank33
Associated DRAM uBank 4→530 SRAM Group B 512: bank00, bank01, bank10, bank11
Associated DRAM uBank 5→532 SRAM Group B 512: bank02, bank03, bank12, bank13
Associated DRAM uBank 6→534 SRAM Group B 512: bank20, bank21, bank30, bank31
Associated DRAM uBank 7→536 SRAM Group B 512: bank22, bank23, bank32, bank33
Associated DRAM uBank 8→SRAM Group C: bank00, bank01, bank10, bank11
Associated DRAM uBank 9→SRAM Group C: bank02, bank03, bank12, bank13
Associated DRAM uBank 10→SRAM Group C: bank20, bank21, bank30, bank31
Associated DRAM uBank 11→SRAM Group C: bank22, bank23, bank32, bank33
Associated DRAM uBank 12→SRAM Group D: bank00, bank01, bank10, bank11
Associated DRAM uBank 13→SRAM Group D: bank02, bank03, bank12, bank13
Associated DRAM uBank 14→SRAM Group D: bank20, bank21, bank30, bank31
Associated DRAM uBank 15→SRAM Group D: bank22, bank23, bank32, bank33

### NPU Core

External LPDDR Interface—A standard LPDDR interface connects the NPU to off-chip DRAM, used for bulk data storage. The interface may include multiple channels and support LPDDR4X/5/5X/6/6X standards.

FIG. 6A illustrates an exemplary Direct Memory Access (DMA) Controller 610 featuring a Copy Engine/Module 622, in accordance with an embodiment of the present invention. The system manages the movement of Weights (W) and Input Feature Maps (X) through a hierarchical memory structure to optimize for high-accuracy, low-power computation. The data transfer and execution flow comprise the following steps:
1. Initial Weight Loading: DMA Controller 610 facilitates the transfer of Weights 620 from External DRAM 612 via DRAM Controller 614. Depending on the tensor size, CXRAM Controller 630 may direct Weights 620 to either local SRAM 616 or Upper Stacked DRAM (UDRAM) 618. Weights that fit within the local capacity are moved directly to SRAM 616. Larger weight sets are buffered in the high-bandwidth UDRAM 618.
2. Weight Reuse and Tiling: For large-scale tensor operations (e.g., matrix multiplication or convolution), Weights 620 often require significant reuse. When the total weight volume exceeds SRAM 616 capacity, the weights are stored in UDRAM 618. Copy Engine 622 then fetches “chunks” (tiles) of these weights into SRAM 616 as needed by Computing Units/PE Processor Units 624.
3. Feature Map Orchestration: Similar to the weight loading process, large Input Feature Maps 626 are transferred from External DRAM 612 to either UDRAM 618 or SRAM 616 based on their dimensions and the requirements of the current compute layer.
4. Data Staging: Copy Engine 622 orchestrates the movement of specific data chunks from upper memory layers (UDRAM) 618 into local SRAM 616 to ensure Computing Units 624 have continuous access to fresh data with minimal latency.
5. Weight Stationary Mode: In a Weight Stationary (WS) configuration, the Weight matrix (W) is pre-loaded and held constant within the local memory cells or buffers of the compute core. This minimizes the energy-intensive movement of weights 620 during high-volume inference.
6. Feature Map Stationary Mode: Alternatively, the system supports a Feature Map Stationary (FS) configuration, where a chunk of the Feature Map is held in a local stationary buffer 626 while multiple weight sets are streamed through for computation.
7. 3D Interconnect Data Path: Weights 620, Feature Maps 626, and Key-Value (KV) Caches (for Transformer-based models) stored in UDRAM 618 are transmitted via Through-Silicon Vias (TSVs) to SRAM 616 or the dedicated stationary buffers of the logic layer for processing by Accumulators 628.
8. Multi-Dimensional Loop Execution: A hardware-managed multi-dimensional loop instruction triggers local Multiply-Accumulate (MAC) operations, producing Partial Sums (Σ). Over successive cycles, weight stationary buffers 620 or feature map stationary buffers 626 are updated as the system iterates through the remaining dimensions of the tensor loop to generate final sums.
9. Post-Processing and Back-Storage: Quantization and Activation Module 636 processes the final accumulated results 634 (e.g., applying ReLU, Sigmoid, or INT8 scaling). The resulting output tensors are stored back into SRAM 616, from where they are either promoted to UDRAM 618 for subsequent layers or forwarded to an external interface.

The region vertically adjacent to and situated above the NPU 608 (Base Die 205) comprises a multi-layered storage and routing complex designed to eliminate the “Memory Wall” in AI inference.

### Elements and Components

Stacked Memory Dies (SRAM/DRAM/MRAM): Multiple layers of high-density memory connected via hybrid bonding.

Through-Silicon Vias (TSVs): Vertical conductive pathways that penetrate the memory dies to provide a direct electrical link to the NPU below.

Silicon Interposer/Redistribution Layer (RDL): A fine-pitch routing layer that spreads signals from the dense NPU micro-bumps to the wider pitch of the memory TSVs.

Decoupling Capacitors (Deep Trench Caps): Integrated into the silicon above the NPU to provide localized energy storage, preventing voltage droop during high-accuracy MAC (Multiply-Accumulate) operations.

### Functional Roles

High-Bandwidth Weight Streaming: The upper layers store the Weights (W). By placing them directly above the NPU, the distance data travels is reduced from millimeters (on a PCB) to micrometers (within the stack).

KV Cache Management: For Generative AI, the upper stack acts as a dedicated buffer for Key-Value pairs, allowing the NPU to “remember” long contexts in LLM conversations without accessing external DRAM.

Partial Sum Aggregation: In multi-core operations, the memory layers above the NPU can serve as a shared “scratchpad” where intermediate computation results (Partial Sums) are temporarily stored and synchronized.

### 3. Strategic Advantages of the NPU

Deterministic Latency: Because the upper elements are hard-wired via TSVs, the time it takes for a Feature Map (X) to reach the NPU is constant. This ensures high-accuracy synchronization that is impossible with variable-latency external memory.

Thermal Isolation: By stacking the memory above the compute, the design can utilize the top surface of the memory stack for a primary heat sink, drawing heat away from the sensitive NPU transistors below.

Reduced Data-Movement Power: Moving data vertically through the upper stack consumes significantly less energy (e.g. $pJ/bit$) than moving data horizontally across a motherboard. This is the cornerstone of the “Very Low Power” conditions.

The upper stacking architecture functions as a localized, high-bandwidth data reservoir that facilitates the near-instantaneous delivery of multi-dimensional tensors to the NPU compute fabric. By integrating a dedicated Redistribution Layer (RDL) between the memory cells and the logic layer, the system achieves a high-integrity signal path that preserves the bit-precision required for high-accuracy neural network execution while minimizing parasitic switching losses.

FIG. 6B illustrates an exemplary Logic Layer Architecture with upper DRAM 618 and external DRAM 612 and Compute in Memory SOC 608, in accordance with an embodiment of the present invention.

Compute-in-Memory (CIM) 608 refers to a specialized hardware block where the memory array 616 (e.g., SRAM or MRAM) and the Multiply-Accumulate (MAC) logic 632 are physically nearly merged. Unlike traditional architectures that fetch weights to a CPU, the CIM architecture applies input signals directly to the word-lines or bit-lines of the memory array, utilizing the physical properties of the cells to perform computations. This drastically reduces data movement, supporting the “very low power” condition.

Computation Controller 624: This is the “Command Center.” Computation Controller 624 decodes the Descriptor-Based instructions and issues specific compute and read/write timing signals to the CIM arrays.

In-Memory MAC Arrays 632: These are the core compute elements. They perform the multiplication of Weights (W) stored in the cells by the Input Feature Maps (X) provided by the controller. These may operate as Digital-CIM for ultra-high accuracy or Analog-CIM for maximum power efficiency.

Accumulator Unit 628: Unit 628 sits at the periphery of the MAC arrays.

Unit 628 aggregates partial results (Partial Sums) from multiple cycles of memory-layer fetching, ensuring the multi-dimensional loops are correctly summed.

Quantization/Activation (Q/A) Module 636: This module processes the high-precision accumulated results. It applies non-linear Activation Functions (e.g., ReLU, GeLU, or Sigmoid) and scales the results back to a lower bit-width (e.g., INT8) for energy-efficient storage.

Bus Interface 670: The high-speed bridge connecting the compute core 608 to CPU 640, IOBus 642, Upper Stacked DRAM 618, and External DRAM 612.

### Operational Flow and Memory Elements

NPU 608 utilizes the following elements to execute its high-efficiency data flow:

Fetch to 3D Memory 618: Input tensors are moved from the External LPDDR 612 into the Upper Stacked DRAM 618. The 3D memory acts as the high-capacity, near-chip buffer for massive datasets that cannot fit in the Base Die.

Copy Engine 622: This module acts as the “Shuttle,” precisely loading working tiles (small chunks of the larger tensor) from 3D memory 618 into the local SRAM 616.

CXRAM_CTRL 630: is configured to control a data transfer mechanism in which data stored in an external memory is transferred directly to SRAM 616 without first being staged in UDRAM 618. In conventional architectures, data is typically fetched from the external memory into UDRAM 618 and subsequently copied from UDRAM 618 to SRAM 616 using a copy engine, resulting in additional memory access and transfer latency.

In contrast, the present architecture provides a shortened data path whereby data is fetched directly from the external memory to SRAM 616 under the control of CXRAM_CTRL 630. Configuration information and control parameters associated with the direct transfer operation are stored in DMA CXRAM 610. By eliminating the intermediate staging step through UDRAM 618, the disclosed mechanism reduces memory access overhead and improves data transfer efficiency and latency.

Compute: Execution occurs using the low-latency SRAM-resident data, ensuring MAC units 624 never stall.

Write-Back: DMA 610 manages the return of intermediate or final outputs to either the 3D memory stack or external system memory.

### Advantages for Marketing

By defining the CIM and 3D stacking in a “Non-Von Neumann” architecture:

Deterministic Accuracy: Because Accumulator Unit 628 is hardened in logic right next to MAC Arrays 624, there is a zero-signal noise from external bus transitions, preserving every bit of precision.

Zero-Latency Weights: Since the weights are “stationary” inside the CIM MAC Arrays 624, the energy cost of fetching a weight is essentially zero.

Scalable “Brain” Layers: Upper Stacked DRAM 618 allows the chip to scale from simple tasks (using only local SRAM) to massive Generative AI tasks (using the full 3D stack) without changing the hardware design.

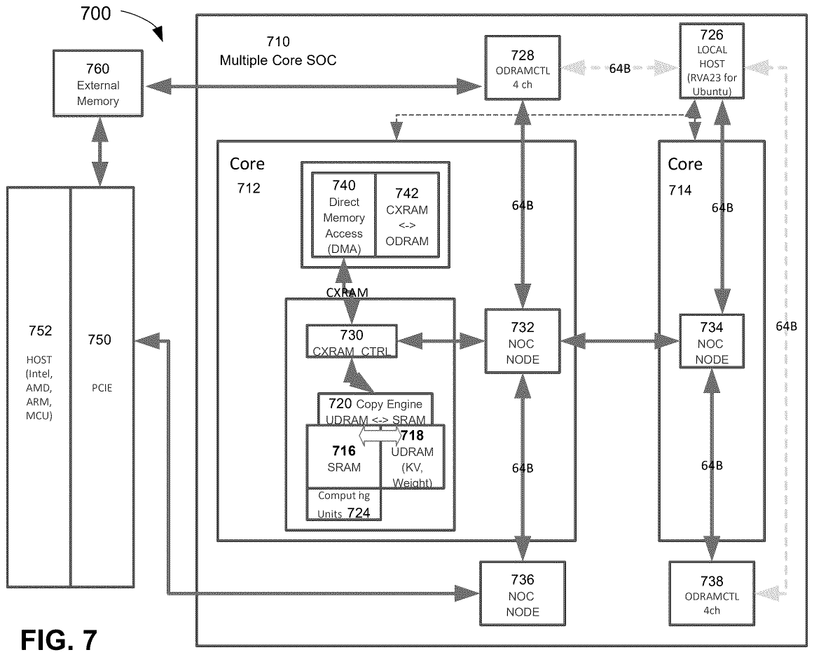

FIG. 7 illustrates an exemplary Multiple Core System on Chip (SOC) 710, in accordance with an embodiment of the present invention. In one embodiment of the present invention, each compute core 712 714 may be interconnected through Network-on-Chip (NoC) 732 734, which enables high-bandwidth, low-latency communication among multiple cores. In one embodiment, each processing core within the system is configured to perform substantially the same set of functions. For example, Core 712 may be configured with the same functional capabilities as Core 714. However, the architecture is not limited to identical functionality among cores, and in other embodiments one or more cores may be configured with differing or specialized functional capabilities. NoC 732, 734, and 736 also provide connectivity between individual compute cores 712 and 714 and shared or large-scale system components, such as, without limitation, external LPDDR DRAM (oDRAM) controllers, PCIe® interfaces 750, and a local host CPU 726. The NoC-based architecture allows scalable data movement and efficient coordination across the entire NPU subsystem 700. Each compute core 712 714 comprises the following functional blocks:
Computation Controller is inside Computing unit 724: Operable for issuing computation commands and coordinating memory read and write operations.
In-Memory MAC Arrays is inside Computing unit 724: Configured for performing analog or digital multiply-accumulate (MAC) operations directly within or near the memory arrays to maximize compute efficiency and minimize data movement.
Accumulator Unit is inside Computing unit 724: Configured to aggregate partial computation results accumulated over multiple cycles while fetching and processing data from stacked memory layers.
Quantization and Activation Module is inside Computing unit 724: Configured to apply activation functions, such as, without limitation, ReLU when enabled, performs bit-width scaling or quantization to support low-precision inference.
Bus Interface PCIE 750: Provides connectivity to external Host CPU 752, and external DRAM devices 760.

NPU 710 integrates both vector and tensor execution units that may be specifically optimized for AI inference workloads. Each compute core 712 primarily accesses local SRAM 716 and 3D-stacked memory (e.g. UDRAM) 718 as first-level data sources, largely enabling low-latency data access and high utilization of compute resources. The architecture may support a layered data movement and execution flow, allowing the NPU to:
Fetch input tensors from external LPDDR memory 760 from interface ODRAMCTL 728 into 3D-stacked memory 718
Utilize a copy engine 720 to transfer active working tiles into local SRAM 716
Execute compute operations using low-latency, SRAM-resident data
Write intermediate or final results back to stacked or external memory via DMA mechanisms 740

In one embodiment, data stored in an external memory may be transferred directly to SRAM 716 without first being staged in UDRAM 718. In conventional approaches, data is typically fetched from the external memory into UDRAM 718 and subsequently copied to SRAM 716 using a copy engine. In contrast, the present architecture enables a shortened data path in which the data is fetched directly from the external memory to SRAM 716 under the control of CXRAN_CTRL 730. The configuration and control parameters for this direct transfer operation are stored in CXRAN_ODRAM 742. This mechanism reduces intermediate memory access and improves data transfer efficiency and latency.

The hierarchical memory and interconnect architecture appreciably improves overall throughput, reduces compute idle time, and significantly enhances energy efficiency, making the NPU well suited for edge and embedded AI devices.

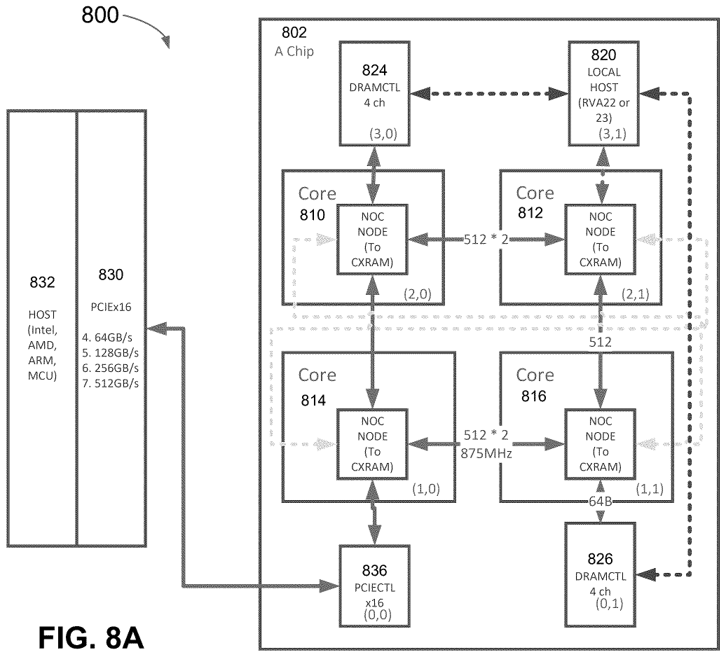

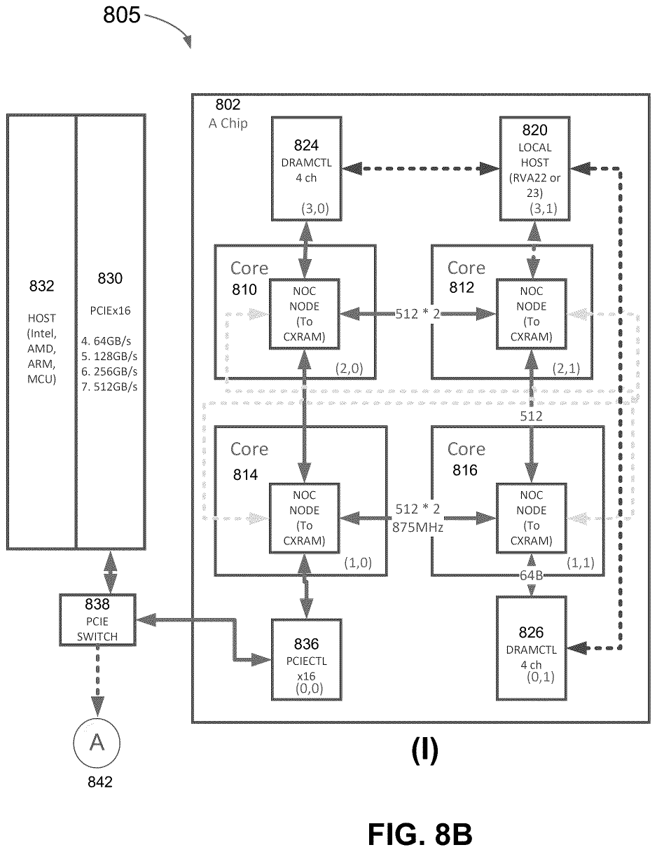

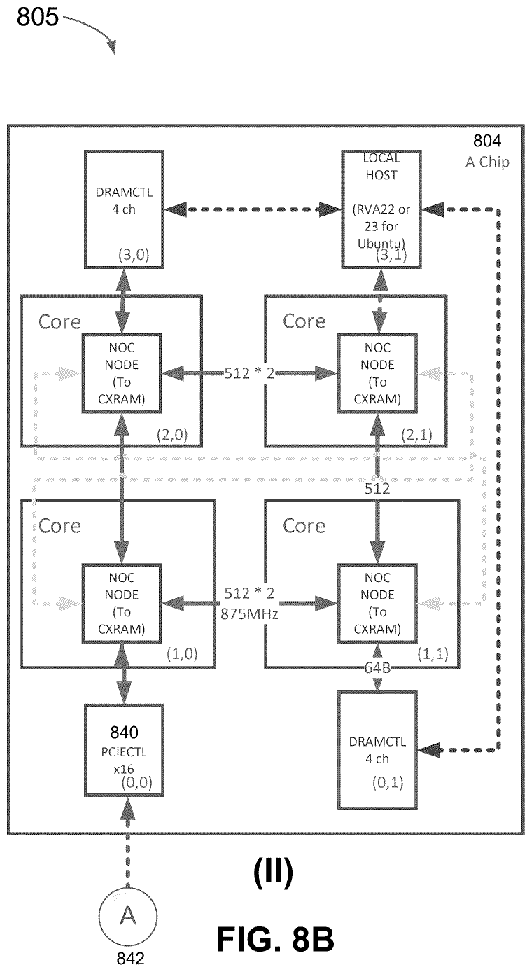

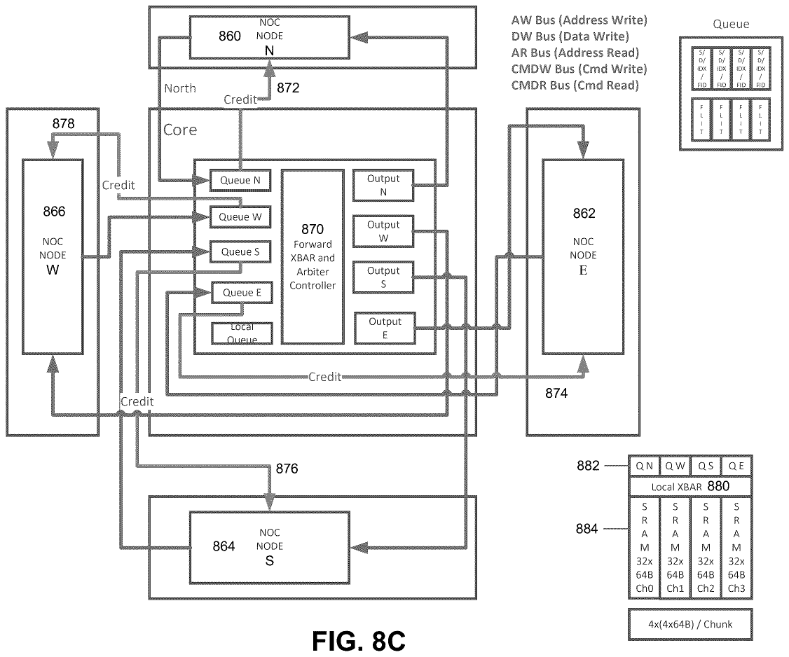

FIG. 8A illustrates an exemplary core-to-core interconnection using a Network-on-Chip (NoC) 800, in accordance with an embodiment of the present invention. The system comprises of four NPU cores 810 812 814 816, a host CPU core 820, and two DRAM controllers 824 826 that interface with external LPDDR or DDR DRAM. Additional off-chip DRAM may be used to supplement the total memory capacity beyond what may be provided by the 3D-stacked DRAM.

Chip 802 may operate as a standalone device or be integrated into a larger host system through a PCIe® interface. The diagram shows a PCIe® x16 connection 830, supporting PCIe® Gen4 through Gen7 depending on system requirements. The host platform 832 may include, without limitation, Intel®, AMD®, Arm-based, or any other MCU-based system.

FIG. 8B illustrates an exemplary NoC topology for core-to-core and chip-to-chip communication 805, in accordance with an embodiment of the present invention. Referring to FIG. 8A and FIG. 8B, (I) and (II), similar to FIG. 8A, in addition to connecting to a host system 832 through PCIe® 830, as shown in FIG. 8B(I), chip 802 may also communicate with another identical chip 804 over a PCIe® x16 link 840 (see FIG. 8B(II)) with a PCIE® switch 838 and interconnect 842, effectively forming a chip-to-chip extension. Interconnect 842 may also be implemented using alternative die-to-die standards such as, without limitation, UCIe or other compatible specifications.

FIG. 8C illustrates an exemplary NOC Queue and Credit for core-to-core communication, in accordance with an embodiment of the present invention. Inside the chip, a Network-on-Chip (NoC) fabric may connect each core and major subsystem. In the design, five input queues may be implemented: four queues receive requests from the four NoC directions (e.g. North (N) 860, West (W) 866, South (S) 864, East (E) 862), and one queue handles local requests. The five queues may be scheduled to route data to four output ports (N, W, S, E). A forward crossbar (XBAR) and arbiter 870 manage the switching of data to the appropriate output direction.

A credit-based feedback mechanism 872 874 876 878 that reports available buffer space back to each requesting NoC interface 860 862 864 866 may be included. When an input queue has free space, it signals its corresponding NoC port that it may accept new requests.

The architecture forwards packets to the next NoC hop when required. If an input queue receives a packet whose destination may be the current local node, the packet may be consumed locally rather than forwarded. Because packets arriving from the four NoC directions may simultaneously target the local destination, small local holding queues (QN, QW, QS, QE) 882 may be included to temporarily store the locally destined packets. A local crossbar 880 then routes the packets into different SRAM banks 884. Once enough data may be accumulated, the packets may be written into the SRAM banks efficiently.

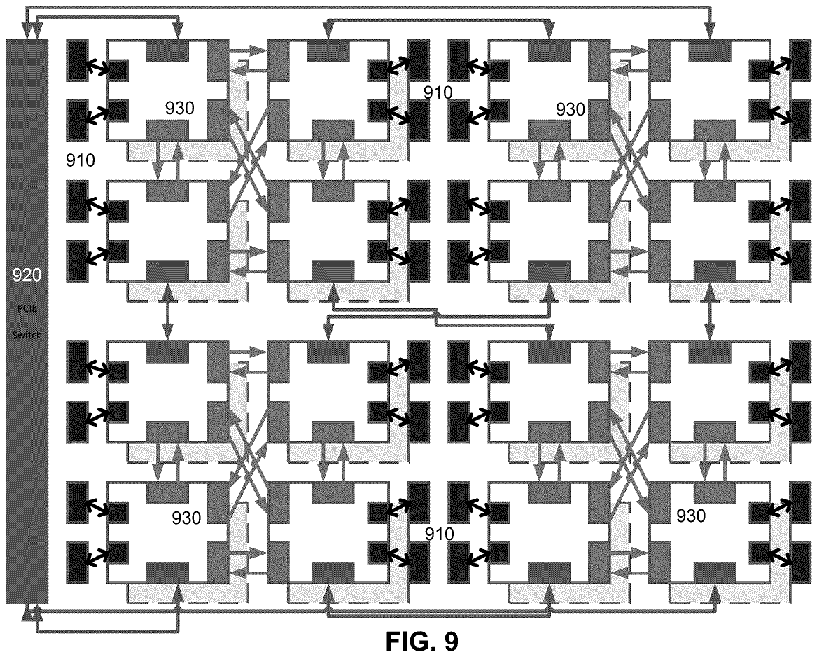

FIG. 9 illustrates an exemplary die-to-die with memory interfaces, in accordance with an embodiment of the present invention. The Chip comprises:
1. A plurality of memory controller modules (e.g. black color) 910, including at least one- or two-DRAM controllers configured to interface with one or more external DRAM devices through corresponding memory channels;
2. A PCIe® interface module (e.g. blue color) 920 configured to establish a high-speed serial interconnect with an external PCIe® switch or with a PCIe® controller of another semiconductor device; and
3. A plurality of die-to-die (D2D) interface modules (e.g. green color) 930, comprising at least one to three D2D interfaces configured to provide direct inter-die communication with a second chip within a multi-chip package or heterogeneous integration system.

Those skilled in the art will readily recognize, in light of and in accordance with the teachings of the present invention, that any of the foregoing steps and/or system modules may be suitably replaced, reordered, removed and additional steps and/or system modules may be inserted depending upon the needs of the particular application, and that the systems of the foregoing embodiments may be implemented using any of a wide variety of suitable processes and system modules, and is not limited to any particular computer hardware, software, middleware, firmware, microcode and the like. For any method steps described in the present application that can be carried out on a computing machine, a typical computer system can, when appropriately configured or designed, serve as a computer system in which those aspects of the invention may be embodied. Such computers referenced and/or described in this disclosure may be any kind of computer, either general purpose, or some specific purpose computer such as, but not limited to, a workstation, a mainframe, GPU, ASIC, etc. The programs may be written in C, or Java, Brew or any other suitable programming language. The programs may be resident on a storage medium, e.g., magnetic or optical, e.g., without limitation, the computer hard drive, a removable disk or media such as, without limitation, a memory stick or SD media, or other removable medium. The programs may also be run over a network, for example, with a server or other machine sending signals to the local machine, which allows the local machine to carry out the operations described herein.

Those skilled in the art will readily recognize, in light of and in accordance with the teachings of the present invention, that any of the foregoing steps may be suitably replaced, reordered, removed and additional steps may be inserted depending upon the needs of the particular application. Moreover, the prescribed method steps of the foregoing embodiments may be implemented using any physical and/or hardware system that those skilled in the art will readily know is suitable in light of the foregoing teachings. For any method steps described in the present application that can be carried out on a computing machine, a typical computer system can, when appropriately configured or designed, serve as a computer system in which those aspects of the invention may be embodied. Thus, the present invention is not limited to any particular tangible means of implementation.

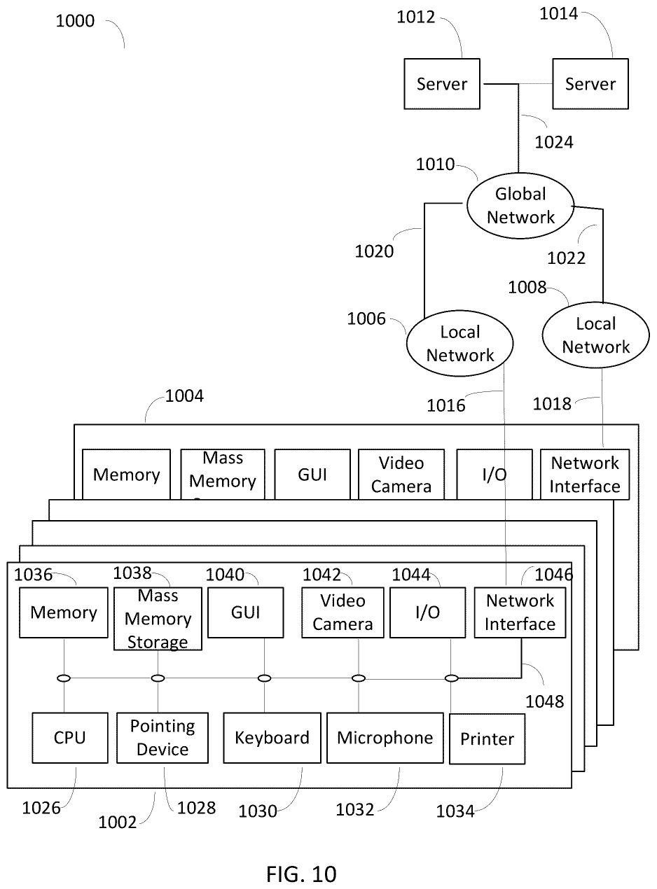

FIG. 10 is a block diagram depicting an exemplary client/server system which may be used by an exemplary web-enabled/networked embodiment of the present invention.

A communication system 1000 includes a multiplicity of clients with a sampling of clients denoted as a client 1002 and a client 1004, a multiplicity of local networks with a sampling of networks denoted as a local network 1006 and a local network 1008, a global network 1010 and a multiplicity of servers with a sampling of servers denoted as a server 1012 and a server 1014.

Client 1002 may communicate bi-directionally with local network 1006 via a communication channel 1016. Client 1004 may communicate bi-directionally with local network 1008 via a communication channel 1018. Local network 1006 may communicate bi-directionally with global network 1010 via a communication channel 1020. Local network 1008 may communicate bi-directionally with global network 1010 via a communication channel 1022. Global network 1010 may communicate bi-directionally with server 1012 and server 1014 via a communication channel 1024. Server 1012 and server 1014 may communicate bi-directionally with each other via communication channel 1024. Furthermore, clients 1002, 1004, local networks 1006, 1008, global network 1010 and servers 1012, 1014 may each communicate bi-directionally with each other.

In one embodiment, global network 1010 may operate as the Internet. It will be understood by those skilled in the art that communication system 1000 may take many different forms. Non-limiting examples of forms for communication system 1000 include local area networks (LANs), wide area networks (WANs), wired telephone networks, wireless networks, or any other network supporting data communication between respective entities.

Clients 1002 and 1004 may take many different forms. Non-limiting examples of clients 1002 and 1004 include personal computers, personal digital assistants (PDAs), cellular phones and smartphones.

Client 1002 includes a CPU 1026, a pointing device 1028, a keyboard 1030, a microphone 1032, a printer 1034, a memory 1036, a mass memory storage 1038, a GUI 1040, a video camera 1042, an input/output interface 1044 and a network interface 1046.

CPU 1026, pointing device 1028, keyboard 1030, microphone 1032, printer 1034, memory 1036, mass memory storage 1038, GUI 1040, video camera 1042, input/output interface 1044 and network interface 1046 may communicate in a unidirectional manner or a bi-directional manner with each other via a communication channel 1048. Communication channel 1048 may be configured as a single communication channel or a multiplicity of communication channels.

CPU 1026 may be comprised of a single processor or multiple processors. CPU 1026 may be of various types including micro-controllers (e.g., with embedded RAM/ROM) and microprocessors such as programmable devices (e.g., RISC or SISC based, or CPLDs and FPGAs) and devices not capable of being programmed such as gate array ASICs (Application Specific Integrated Circuits) or general-purpose microprocessors.

As is well known in the art, memory 1036 is used typically to transfer data and instructions to CPU 1026 in a bi-directional manner. Memory 1036, as discussed previously, may include any suitable computer-readable media, intended for data storage, such as those described above excluding any wired or wireless transmissions unless specifically noted. Mass memory storage 1038 may also be coupled bi-directionally to CPU 1026 and provides additional data storage capacity and may include any of the computer-readable media described above. Mass memory storage 1038 may be used to store programs, data and the like and is typically a secondary storage medium such as a hard disk. It will be appreciated that the information retained within mass memory storage 1038, may, in appropriate cases, be incorporated in standard fashion as part of memory 1036 as virtual memory.

CPU 1026 may be coupled to GUI 1040. GUI 1040 enables a user to view the operation of computer operating systems and software. CPU 1026 may be coupled to pointing device 1028. Non-limiting examples of pointing device 1028 include computer mouse, trackball and touchpad. Pointing device 1028 enables a user with the capability to maneuver a computer cursor about the viewing area of GUI 1040 and select areas or features in the viewing area of GUI 1040. CPU 1026 may be coupled to keyboard 1030. Keyboard 1030 enables a user with the capability to input alphanumeric textual information to CPU 1026. CPU 1026 may be coupled to microphone 1032. Microphone 1032 enables audio produced by a user to be recorded, processed and communicated by CPU 1026. CPU 1026 may be connected to printer 1034. Printer 1034 enables a user with the capability to print information to a sheet of paper. CPU 1026 may be connected to video camera 1042. Video camera 1042 enables video produced or captured by user to be recorded, processed and communicated by CPU 1026.

CPU 1026 may also be coupled to input/output interface 1044 that connects to one or more input/output devices such as such as CD-ROM, video monitors, track balls, mice, keyboards, microphones, touch-sensitive displays, transducer card readers, magnetic or paper tape readers, tablets, styluses, voice or handwriting recognizers, or other well-known input devices such as, of course, other computers.

Finally, CPU 1026 optionally may be coupled to network interface 1046 which enables communication with an external device such as a database or a computer or telecommunications or internet network using an external connection shown generally as communication channel 1016, which may be implemented as a hardwired or wireless communications link using suitable conventional technologies. With such a connection, CPU 1026 might receive information from the network, or might output information to a network in the course of performing the method steps described in the teachings of the present invention.

All the features disclosed in this specification, including any accompanying abstract and drawings, may be replaced by alternative features serving the same, equivalent or similar purpose, unless expressly stated otherwise. Thus, unless expressly stated otherwise, each feature disclosed is one example only of a generic series of equivalent or similar features.

It is noted that according to USA law 35 USC § 112 (1), all claims must be supported by sufficient disclosure in the present patent specification, and any material known to those skilled in the art need not be explicitly disclosed. However, 35 USC § 112 (6) requires that structures corresponding to functional limitations interpreted under 35 USC § 112 (6) must be explicitly disclosed in the patent specification. Moreover, the USPTO's Examination policy of initially treating and searching prior art under the broadest interpretation of a “mean for” or “steps for” claim limitation implies that the broadest initial search on 35 USC § 112(6) (post AIA 112(f)) functional limitation would have to be conducted to support a legally valid Examination on that USPTO policy for broadest interpretation of “mean for” claims. Accordingly, the USPTO will have discovered a multiplicity of prior art documents including disclosure of specific structures and elements which are suitable to act as corresponding structures to satisfy all functional limitations in the below claims that are interpreted under 35 USC § 112(6) (post AIA 112(f)) when such corresponding structures are not explicitly disclosed in the foregoing patent specification. Therefore, for any invention element(s)/structure(s) corresponding to functional claim limitation(s), in the below claims interpreted under 35 USC § 112(6) (post AIA 112(f)), which is/are not explicitly disclosed in the foregoing patent specification, yet do exist in the patent and/or non-patent documents found during the course of USPTO searching, Applicant(s) incorporate all such functionally corresponding structures and related enabling material herein by reference for the purpose of providing explicit structures that implement the functional means claimed. Applicant(s) request(s) that fact finders during any claims construction proceedings and/or examination of patent allowability properly identify and incorporate only the portions of each of these documents discovered during the broadest interpretation search of 35 USC § 112(6) (post AIA 112(f)) limitation, which exist in at least one of the patent and/or non-patent documents found during the course of normal USPTO searching and or supplied to the USPTO during prosecution. Applicant(s) also incorporate by reference the bibliographic citation information to identify all such documents comprising functionally corresponding structures and related enabling material as listed in any PTO Form-892 or likewise any information disclosure statements (IDS) entered into the present patent application by the USPTO or Applicant(s) or any 3^{rd} parties. Applicant(s) also reserve the right to later amend the present application to explicitly include citations to such documents and/or explicitly include the functionally corresponding structures which were incorporated by reference above.

Thus, for any invention element(s)/structure(s) corresponding to functional claim limitation(s), in the below claims, that are interpreted under 35 USC § 112(6) (post AIA 112(f)), which is/are not explicitly disclosed in the foregoing patent specification, Applicant(s) have explicitly prescribed which documents and material to include the otherwise missing disclosure, and have prescribed exactly which portions of such patent and/or non-patent documents should be incorporated by such reference for the purpose of satisfying the disclosure requirements of 35 USC § 112 (6). Applicant(s) note that all the identified documents above which are incorporated by reference to satisfy 35 USC § 112 (6) necessarily have a filing and/or publication date prior to that of the instant application and thus are valid prior documents to incorporated by reference in the instant application.

Having fully described at least one embodiment of the present invention, other equivalent or alternative methods of implementing compute-in-memory (CIM) architecture integrated within 3D stacked memory devices for efficient data processing in artificial intelligence and edge computing environments according to the present invention will be apparent to those skilled in the art. Various aspects of the invention have been described above by way of illustration, and the specific embodiments disclosed are not intended to limit the invention to the particular forms disclosed. The particular implementation of the compute-in-memory (CIM) architecture integrated within 3D stacked memory devices for efficient data processing in artificial intelligence and edge computing environments may vary depending upon the particular context or application. By way of example, and not limitation, the compute-in-memory (CIM) architecture integrated within 3D stacked memory devices described in the foregoing were principally directed to efficient data processing in artificial intelligence and edge computing environment implementations; however, similar techniques may instead be applied to:

Real-Time Physics and Digital Twin Simulations: The eight-dimensional tensor descriptor and 3D-stacked CIM architecture are uniquely suited for solving complex partial differential equations (PDEs) and Finite Element Analysis (FEA). This includes real-time fluid dynamics, thermal modeling in aerospace, and high-fidelity digital twins of industrial manufacturing lines where low-latency “compute-near-data” is mandatory.

Fully Homomorphic Encryption (FHE) and Secure Multi-Party Computation: The massive parallelism and high-accuracy partial sum accumulation of the NPU can be repurposed for “computing on encrypted data.” FHE requires enormous polynomial multiplications that traditional CPUs cannot handle efficiently; the disclosed CIM architecture provides the necessary bandwidth to perform these secure operations at the edge without decrypting sensitive data.

Bioinformatics and Genomic Sequence Alignment: The multi-dimensional loop structures managed by the Base Die can be used for high-speed Smith-Waterman or Burrows-Wheeler transformations. This allows for portable, battery-powered DNA sequencing devices that require high-accuracy pattern matching against massive genomic databases stored in the upper 3D memory layers.

Autonomous Signal Intelligence (SIGINT) and 6G Beamforming: The architecture can be applied to real-time, high-accuracy Fast Fourier Transforms (FFTs) and complex matrix inversions required for 6G massive MIMO antenna arrays. By processing signal tensors directly in the stacked memory, the system can adapt beamforming patterns in microseconds with minimal power draw.

Furthermore, the disclosed architecture contemplates a heterogeneous resilience model, where the logic layer (Base Die) may dynamically reallocate compute resources between AI-specific MAC operations and general-purpose tensor arithmetic based on real-time workload demands, ensuring optimal hardware utilization across diverse computational domains.

Which implementations of the present invention are contemplated as within the scope of the present invention. The invention is thus to cover all modifications, equivalents, and alternatives falling within the spirit and scope of the following claims. It is to be further understood that not all of the disclosed embodiments in the foregoing specification will necessarily satisfy or achieve each of the objects, advantages, or improvements described in the foregoing specification.

Claim elements and steps herein may have been numbered and/or lettered solely as an aid in readability and understanding. Any such numbering and lettering in itself is not intended to and should not be taken to indicate the ordering of elements and/or steps in the claims.

The corresponding structures, materials, acts, and equivalents of all means or step plus function elements in the claims below are intended to include any structure, material, or act for performing the function in combination with other claimed elements as specifically claimed.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The Abstract is provided to comply with 37 C.F.R. Section 1.72(b) requiring an abstract that will allow the reader to ascertain the nature and gist of the technical disclosure. That is, the Abstract is provided merely to introduce certain concepts and not to identify any key or essential features of the claimed subject matter. It is submitted with the understanding that it will not be used to limit or interpret the scope or meaning of the claims.

The following claims are hereby incorporated into the detailed description, with each claim standing on its own as a separate embodiment.

Only those claims which employ the words “means for” or “steps for” are to be interpreted under 35 USC 112, sixth paragraph (pre-AIA) or 35 USC 112(f) post-AIA. Otherwise, no limitations from the specification are to be read into any claims, unless those limitations are expressly included in the claims.

What is claimed is:

1. A processing unit, comprising:
a first die, said first die comprises a compute core;
wherein said compute core comprises a first interconnect surface area;
a second die, said second die comprises a three-dimensionally (3D) stacked memory;
wherein said three-dimensionally (3D) stacked memory comprises a second interconnect surface area;
wherein said second die is configured interconnect with said first die in a stacked configuration;
in which said first die further comprises:
an internal SRAM, wherein said internal SRAM is configured to provide said compute core with the next set of data ready, eliminating the energy waste of idle cycles;
a direct memory access (DMA) controller, said direct memory access (DMA) controller comprising:
a copy module, wherein said copy module is configured to be operable for transferring data between said three-dimensionally stacked memory and said internal SRAM;
a logic layer, wherein said logic layer is configured to be operable for transferring data between said internal SRAM and an external memory, the external memory comprises at least one of LPDDR, GDDR or DDR;
wherein said logic layer is further configured to be operable for transferring data between said three-dimensionally (3D) stacked memory and said external memory; and
a high-speed input/output (IO) interface; and
wherein said high-speed input/output (IO) interface is mainly routed beneath said compute core to electrically isolate said compute core from said three-dimensionally (3D) stacked memory.

2. The processing unit of claim, wherein said copy module is integrated within said DMA controller and operates independently of said external memory.

3. The processing unit of claim, wherein said first die and second die are interconnected using at least one of a through-silicon vias (TSVs) and micro-bump in a face-to-back (F2B) configuration using hybrid bonding interconnection.

4. The processing unit of claim, wherein one or more data transfer operation(s) performed by said copy module are programmable and execute concurrently with computation operations using double buffering.

5. The processing unit of claim, wherein said high-speed IO interface comprises at least one of LPDDR or PCIe signal(s) routed beneath said logic layer and electrically isolated from the stacked memory to reduce signal interference.

6. The processing unit of claim, further comprising an instruction decoder configured to decode a multi-dimensional instruction defining at least one of a spatial dimension parameter and a temporal dimension parameter.

7. The processing unit of claim, wherein the spatial dimension parameter defines a number of parallel processing lanes and the temporal dimension parameter defines a sequence of iterative operations.

8. The processing unit of claim, further comprising an on-chip local storage, wherein said on-chip local storage is configured to be operable for managing at least one of a feature map, a weight, and a partial sum locally stagnant during a sequence of neural network computations.

9. The processing unit of claim, wherein the local storage comprises a weight register bank, a feature map buffer, and an accumulator register configured to store one or more partial sum(s) until completion of a computation.

10. The processing unit of claim, wherein the three-dimensionally (3D) stacked memory comprises at least a DRAM, wherein the DRAM is configured to be operable for externally accessible through an external memory interface on the first die.

11. The processing unit of claim, wherein said processing unit is a neural processing unit (NPU), wherein said neural processing unit (NPU) is packaged within an integrated circuit module that is operable to be populated on circuit boards by OEMs for end-use distribution.

12. A processing unit comprising:
a base die, said base die comprises at least one logic layer;
a plurality of stacked memory layers;
wherein said at least one logic layer being disposed beneath or between said plurality of stacked memory layers;
wherein each of said plurality of stacked memory layers comprise at least a memory bank of that is operable for performing localized computations;
at least one or more through-silicon vias (TSVs), wherein said one or more through-silicon vias (TSV(s)) is/are configured to electrically interconnect each of said plurality of stacked memory layers to said at least one logic layer;
wherein said logic layer is configured to perform arithmetic operations directly within or proximate to said plurality of vertically stacked memory layer; and
wherein said logic layer comprises at least one buffer structure, and wherein said buffer structure is configured to be operable for maintaining at least one of a weight, a feature map, and a partial sum locally stagnant during computation.

13. The processing unit of claim, wherein the logic layer comprises:
a computation controller, wherein said computation controller is operable for issuing computation commands and coordinating memory read and write operations;
an accumulation unit, wherein said accumulation unit is configured to aggregate partial computation results accumulated over multiple cycles while fetching and processing data from stacked memory layers; and
an activation and quantization module, wherein said activation and quantization module is configured to perform bit-width scaling or quantization to support low-precision inference.

14. The processing unit of claim, wherein the memory layers comprise one or more DRAM(s), SRAM(s), RRAM(s), and/or MRAM(s).

15. The processing unit of claim, further comprising an inter-layer dataflow path that is configured to aggregate partial sums through at least one of the TSV interconnects.

16. The processing unit of claim, wherein the logic layer supports at least one of a digital, an analog or hybrid compute-in-memory operations.

17. The processing unit of claim, wherein the architecture supports quantized computation having a precision between 1-bit, 2-bit, 4-bit and/or 8-bit per operand.

18. The processing unit of claim, wherein the logic layer is coupled to an external processing unit via an interface selected from at least one of a PCIe, an AXI and/or an on-chip interconnect.

19. The processing unit of claim, wherein a feature map, a weight and/or a partial sum is/are maintained locally stagnant within at least one of the memory layer and/or the logic layer during a sequence of arithmetic operations.

20. The processing unit of claim, wherein the stacked memory layer is vertically integrated above the logic layer base die in a face-to-face (F2F) configuration or a face-to-back (F2B) configuration utilizing direct or hybrid bonding.

21. The processing unit of claim, further comprising:
a direct memory access (DMA) controller;
wherein said direct memory access (DMA) controller is configured to transfer data between said vertically stacked memory layers and said logic layer;
wherein said direct memory access (DMA) controller is further configured to transfer data between the vertically stacked memory layers or the logic layer and an external memory or host system via an interface selected from LPDDR, GDDR, DDR, or PCIe; and
wherein said DMA controller operates independently of arithmetic execution in the logic layer.

22. The processing unit of claim, further comprising:
at least one or more memory bank(s) contained in each of said one or more vertically stacked memory layer(s);
at least one or more SRAM bank(s) contained in said logic layer;
wherein each of said one or more memory bank(s) in said stacked memory layer(s) is/are statically or dynamically associated with a corresponding SRAM bank in the logic layer to form an associated bank group; and
wherein data movement is restricted to occur only within an associated bank group and is prevented from crossing into non-associated memory or SRAM bank.

23. The processing unit of claim, further comprising a compute-in-memory processing unit that is packaged within an integrated circuit module that is operable to be populated on circuit boards by OEMs for end-use distribution.

24. A processing unit, comprising:
a base die, said base die comprises at least one compute core;
where said compute core comprises a first interconnect surface area;
a second die, said second die comprises a three-dimensionally (3D) stacked memory layer;
wherein said three-dimensionally (3D) stacked memory layer comprises a second interconnect surface area;
wherein said second die is configured to vertically stack on said first die;
wherein the second surface area of said three-dimensionally (3D) stacked memory layer is interconnected to the first surface area of said compute core in a stacked configuration;
at least one or more through-silicon vias (TSVs), wherein said one or more through-silicon vias (TSV(s)) is/are configured to electrically interconnect said three-dimensionally (3D) stacked memory layer to said computer core;
in which said base die further comprises:
an internal SRAM, wherein said internal SRAM is configured to provide said compute core with the next set of data ready, eliminating the energy waste of idle cycles;
a direct memory access (DMA) controller, said direct memory access (DMA) controller comprising:
a copy engine or module, wherein said copy engine or module is configured to be operable for transferring data between said three-dimensionally (3D) stacked memory layer and said internal SRAM;
a logic layer, wherein said logic layer is configured to be operable for transferring data between said internal SRAM and an external memory, said external memory comprises at least one of LPDDR, GDDR or DDR; and
wherein said logic layer is further configured to be operable for transferring data between said three-dimensionally (3D) stacked memory layer and said external memory.

25. The processing unit of claim, wherein said three-dimensionally (3D) stacked memory layer and said compute core are interconnected in a face-to-back (F2B) stacked configuration.

26. The processing unit of claim, wherein the interconnection utilizes at least one of a bump and a micro-bump.

27. The processing unit of claim, wherein the interconnection utilizes at least one of a direct bonding and a hybrid bonding.

28. The processing unit of claim, wherein said three-dimensionally (3D) stacked memory layer and said compute core are interconnected in a face-to-face (F2F) stacked configuration, wherein the interconnection comprises at least one of a bump, a micro-bump, a direct bonding or a hybrid bonding.

29. The processing unit of claim, further comprising:
a high-speed input/output (IO) interface; and wherein said high-speed input/output (IO) interface is mainly routed beneath said compute core to electrically isolate said compute core from said three-dimensionally (3D) stacked memory layer.

30. The processing unit of claim, wherein a feature map, a weight and/or a partial sum is/are maintained locally stagnant within at least one of said three-dimensionally (3D) stacked memory layer and/or the logic layer during a sequence of arithmetic operations.
